(19) United States
(12) Patent Application Publication
(10) Pub. No.: US 2026/0181876 A1
(43) Pub. Date: Jun. 25, 2026

(54) SEMICONDUCTOR DEVICE INCLUDING MEMORY CELL ARRAY REGIONS AND INTERFACE REGION

(71) Applicant: Samsung Electronics Co., Ltd., Suwon-si (KR)

(72) Inventors: Taejin Park, Suwon-si (KR); Daesun Kim, Suwon-si (KR); Hyeonkyu Lee, Suwon-si (KR); Sungsoo Yim, Suwon-si (KR)

(21) Appl. No.: 19/389,767

(22) Filed: Nov. 14, 2025

(30) Foreign Application Priority Data
Dec. 23, 2024 (KR) 10-2024-0194389

(51) Int. Cl. H10B 12/00; G11C 5/06

(52) U.S. Cl. CPC H10B 12/488; G11C 5/063; H10B 12/02; H10B 12/315; H10B 12/482

(57) ABSTRACT

A semiconductor device is provided. The semiconductor device comprises: first and memory cell array regions spaced apart from each other; a first interface region between the first and second memory cell array regions; first and second word lines crossing the first memory cell array region, the first interface region, and the second memory cell array region; a first back gate electrode between the first and second word lines in the first memory cell array region, and extending into the first interface region; and a first back gate dielectric layer. The first back gate dielectric layer comprises a first portion between the first word line and the first back gate electrode in the first memory cell array region, and a second portion between the second word line and the first back gate electrode.

### CROSS-REFERENCE TO RELATED APPLICATION(S)

This application claims benefit of priority to Korean Patent Application No. 10-2024-0194389 filed on Dec. 23, 2024 in the Korean Intellectual Property Office, the disclosure of which is incorporated herein by reference in its entirety.

### BACKGROUND

Example embodiments relate to a semiconductor device including memory cell array regions and an interface region between the memory cell array regions, and a method for forming a semiconductor device.

Research is being conducted to reduce the sizes of elements constituting a semiconductor device and to improve performance thereof. For example, research is being conducted to reliably and stably form elements with reduced sizes, but as the sizes of the elements are reduced, a dispersion property of the semiconductor device is deteriorating.

### SUMMARY

Example embodiments provide a semiconductor device capable of increasing a degree of integration.

Example embodiments provide a method for forming the semiconductor device.

According to example embodiments, a semiconductor device comprises: a first memory cell array region and a second memory cell array region spaced apart from each other in a first horizontal direction; a first interface region between the first and second memory cell array regions; a first word line and a second word line crossing the first memory cell array region, the first interface region, and the second memory cell array region, and spaced apart from each other in a second horizontal direction, perpendicular to the first horizontal direction; a first back gate electrode between the first and second word lines in the first memory cell array region, and extending into the first interface region; and a first back gate dielectric layer between the first and second word lines, and crossing the first memory cell array region, the first interface region, and the second memory cell array region, wherein the first back gate dielectric layer comprises a first portion between the first word line and the first back gate electrode in the first memory cell array region, and a second portion between the second word line and the first back gate electrode in the first memory cell array region.

According to example embodiments, a semiconductor device comprises: a first memory cell array region and a second memory cell array region spaced apart from each other in a first horizontal direction; a first interface region between the first and second memory cell array regions; and word lines crossing the first memory cell array region, the first interface region, and the second memory cell array region, and spaced apart from each other in a second horizontal direction, perpendicular to the first horizontal direction, wherein the word lines include a first word line and a second word line adjacent to each other, and a minimum distance between the first and second word lines in the first memory cell array region is greater than a minimum distance between the first and second word lines in the first interface region.

According to example embodiments, a semiconductor device comprises: a first structure comprising a first bank area comprising memory cells; and a second structure comprising a second bank area comprising peripheral circuitry, wherein the second structure vertically overlaps the first structure, and the first bank area comprises: a first memory cell array region and a second memory cell array region spaced apart from each other in a first horizontal direction; a first interface region between the first and second memory cell array regions; and a first word line and a second word line crossing the first memory cell array region, the first interface region and the second memory cell array region, and spaced apart from each other in a second horizontal direction, perpendicular to the first horizontal direction, and a minimum distance between the first and second word lines in the first memory cell array region is greater than a minimum distance between the first and second word lines in the first interface region.

### BRIEF DESCRIPTION OF DRAWINGS

The above and other aspects, features, and advantages of the present inventive concept will be more clearly understood from the following detailed description, taken in conjunction with the accompanying drawings, in which:

FIGS. 1A, 1B, 2 and 3 are diagrams illustrating a semiconductor device according to an embodiment of the present inventive concept;

FIG. 4 is a perspective view conceptually illustrating an example of a semiconductor device according to an embodiment of the present inventive concept;

FIGS. 5A, 5B, 6A, 6B, 6C, 7A, 7B, 8 and 9 are drawings illustrating an example of a semiconductor device according to an embodiment of the present inventive concept;

FIG. 10 is a cross-sectional view illustrating an example of a semiconductor device according to an embodiment of the present inventive concept;

FIG. 11 is a cross-sectional view illustrating an example of a semiconductor device according to an embodiment of the present inventive concept;

FIGS. 12A, 12B and 13 are drawings illustrating an example of a semiconductor device according to an embodiment of the present inventive concept;

FIG. 14 is a cross-sectional view illustrating an example of a semiconductor device according to an embodiment of the present inventive concept;

FIGS. 15, 16 and 17 are drawings illustrating an example of semiconductor devices according to an embodiment of the present inventive concept; and

FIGS. 18, 19A, 19B, 19C, 20, 21A, 21B, 21C, 22A, 22B, 22C, 23A, 23B, 23C, 24A, 24B and 24C are drawings illustrating an example of a method for forming a semiconductor device according to an embodiment of the present inventive concept.

### DETAILED DESCRIPTION

Hereinafter, ordinal numbers such as “first,” “second,” “third,” etc. may be used simply as labels of certain elements, steps, etc., to distinguish such elements, steps, etc. from each other. For example, terms such as “upper,” “middle” and “lower” may be replaced with other terms, such as “first,” “second” and “third,” to describe elements of the specification. Although terms such as “first,” “second” and “third” may be used to describe various elements, the elements are not limited by the terms, and a “first element” may be referred to as a “second element.” In the specification, terms such as “lower,” “upper,” “top” and “bottom” may be terms described based on the drawings.

Items described in the singular herein may be provided in plural, as can be seen, for example, in the drawings. Thus, the description of a single item that is provided in plural should be understood to be applicable to the remaining plurality of items unless context indicates otherwise.

Throughout the specification, when a component is described as “including” a particular element or group of elements, it is to be understood that the component is formed of only the element or the group of elements, or the element or group of elements may be combined with additional elements to form the component, unless the context indicates otherwise. The term “consisting of,” on the other hand, indicates that a component is formed only of the element(s) listed.

Terms such as “same,” “equal,” “constant,” “flat,” etc. as used herein, are intended to encompass meanings that include typical variations resulting from conventional manufacturing processes and/or accommodate tolerances acceptable in the manufacturing process of the semiconductor device, unless the context or other statements indicate otherwise. For example, ‘same’ and ‘equal’ may encompass identicality or near identicality. The term “substantially” may be used herein to emphasize this meaning.

In the specification, a “memory cell array region” may refer to a region in which memory cells are disposed. In the specification, an “interface region” may be a region adjacent to the memory cell array region, and may be a region in which the memory cells are not disposed and word line contacts connected to word lines are disposed, a region in which a back gate contact connected to a back gate electrode is disposed, or a region in which bit line contacts connected to bit lines are disposed.

As used herein, the term “dummy” is used to refer to a component that has the same or similar structure and shape as other components but does not have a substantial function (e.g., to convey information). The “dummy” element may only exist as a pattern in the device. In some instances, a “dummy” element may be electrically floated, or may be connected to various voltage sources but otherwise not provide the same functionality of the non-dummy element it represents. For example, a dummy word line may not connect to memory cells, or may have dummy memory cells connected to it (where no data is read from the dummy memory cells). For example, in the specification, among active patterns disposed in the memory cell array regions, an active pattern electrically connected to a bit line and a data storage structure may be a cell active pattern (e.g., with similar structure) that is not, and an active pattern electrically connected to one or both of a bit line and a data storage structure may be a dummy active pattern.

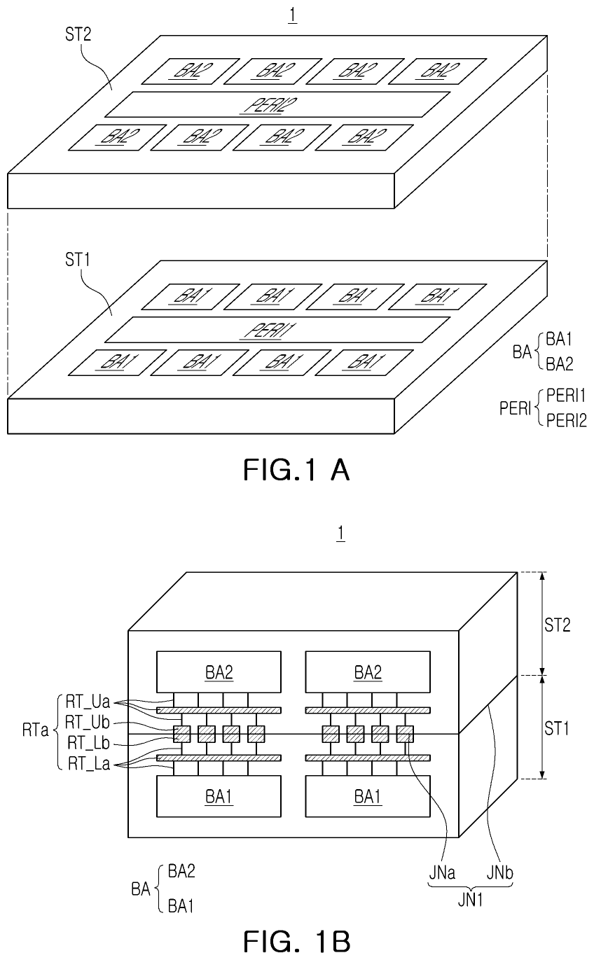

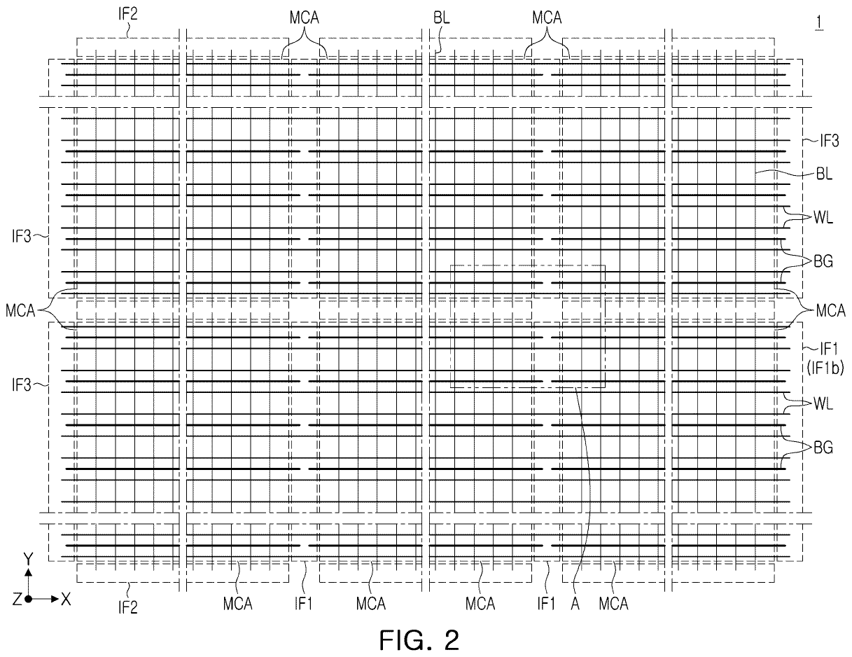

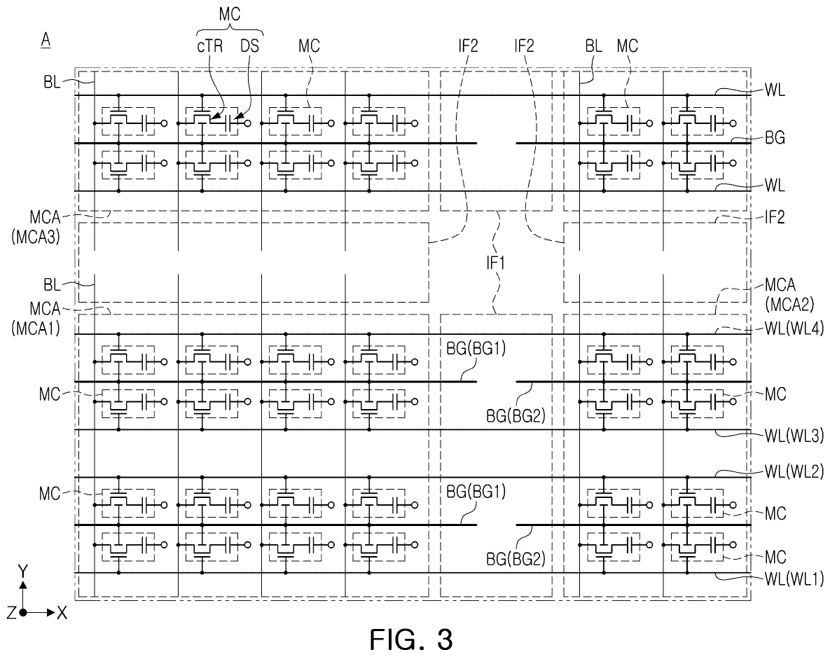

First, a semiconductor device 1 according to an embodiment of the present inventive concept will be described with reference to FIGS. 1A, 1B, 2 and 3. FIGS. 1A, 1B, 2 and 3 are drawings illustrating the semiconductor device 1 according to an embodiment of the present inventive concept, wherein FIG. 1A is a perspective view conceptually illustrating the semiconductor device 1, FIG. 1B is a perspective view conceptually illustrating an electrical connection relationship between first and second structures ST1 and ST2 of FIG. 1, FIG. 2 is a plan view conceptually illustrating a portion of the first structure ST1 of FIG. 1A and FIG. 1B, and FIG. 3 is a circuit diagram illustrating a circuit of an area indicated by ‘A’ in FIG. 2.

Referring to FIGS. 1A, 1B, 2 and 3, the semiconductor device 1 according to an embodiment of the present inventive concept may include the first structure ST1 and the second structure ST2 vertically overlapping the first structure ST1. The second structure ST2 may be disposed on the first structure ST1. According to an embodiment, the second structure ST2 may be disposed below the first structure ST1.

In one embodiment, the first structure ST1 may be a first chip including memory cells (MC in FIG. 3) and a portion of peripheral circuitry regions PERI, and the second structure ST2 may be a second chip including other portions of the peripheral circuitry regions PERI. The peripheral circuitry regions PERI may include first and second peripheral circuitry regions PERI1 and PERI2. In the peripheral circuitry regions PERI, a portion of peripheral circuitry, which is used for operations of the memory cells MC, is formed.

In one embodiment, the first structure ST1 and the second structure ST2 may be bonded by means of a bonding process such as a wafer bonding process. For example, the first structure ST1 may be bonded to the second structure ST2 while being in contact therewith.

The semiconductor device 1 may include a plurality of bank areas BA and peripheral regions PERI.

The peripheral region PERI may include a first peripheral region PERI1 in the first structure ST1 and a second peripheral region PERI2 in the second structure ST2. The peripheral region PERI may be a peripheral region in which first peripheral circuitry for input/output of data or commands, or input of power/ground is disposed.

Each of the plurality of bank areas BA may include a first bank area BA1 in the first structure ST1 and a second bank area BA2 in the second structure ST2. In the first bank area BA1, the memory cells (MC in FIG. 3) may be formed. In the second bank area BA2, second peripheral circuitry may be formed. The second peripheral circuitry may include a sub-word line driver. For example, circuitry in each pair of a first bank area BA1 and a corresponding second bank area BA2 may constitute a bank.

The first and second structures ST1 and ST2 may further include a routing interconnection structure RTa electrically connecting the first bank area BA1 and the second bank area BA2. For example, the routing interconnection structure RTa may include a first routing interconnection structure RT_La and RT_Lb disposed in the first structure ST1 and a second routing interconnection structure RT_Ua and RT_Ub disposed in the second structure ST2.

The first routing interconnection structure RT_La and RT_Lb may include a first interconnection structure RT_La electrically connected to the first bank area BA1 and first bonding pads RT_Lb electrically connected to the first interconnection structure RT_La. The second routing interconnection structure RT_Ua and RT_Ub may include a second interconnection structure RT_Ua electrically connected to the second bank area BA2 and second bonding pads RT_Ub electrically connected to the second interconnection structure RT_Ua.

The first bonding pads RT_Lb and the second bonding pads RT_Ub may be in contact with and bonded to each other. For example, the first bonding pads RT_Lb and the second bonding pads RT_Ub may include copper, and may be bonded to each other by a metal-to-metal bonding process. Accordingly, a bonding surface JN1 between the first structure ST1 and the second structure ST2 may include intermetallic bonding regions JNa in which the first bonding pads RT_Lb of the first structure ST1 and the second bonding pads RT_Ub of the second structure ST2 are bonded to each other, and interdielectric bonding regions JNb in which a dielectric of the first structure ST1 and a dielectric of the second structure ST2 are bonded to each other.

In the first structure ST1, each first bank area BA1 may include memory cell array regions (MCA in FIGS. 2 and 3) and interface regions (IF1, IF2 and IF3 in FIGS. 2 and 3) adjacent to the memory cell array regions MCA.

The memory cell array regions MCA may be arranged in a first horizontal direction X and a second horizontal direction Y that are perpendicular to each other. The interface regions IF1, IF2 and IF3 may include first interface regions IF1 disposed between the memory cell array regions MCA arranged in the first horizontal direction X, third interface regions IF3 disposed at the outermost side in the first horizontal direction X, and second interface regions IF2 adjacent to the memory cell array regions MCA in the second horizontal direction Y. The memory cell array regions MCA and the first interface regions IF1 arranged in the first horizontal direction X may be disposed between the third interface regions IF3. Each of the first interface regions IF1 may be disposed between the memory cell array regions MCA adjacent to each other in the first horizontal direction X.

The memory cell array regions MCA may be regions in which the memory cells MC are disposed. That is, the memory cells MC may be disposed in the memory cell array regions MCA.

Each of the memory cells MC may include a data storage structure DS that may serve to store data, and a cell transistor cTR electrically connected to the data storage structure DS. In a memory such as a DRAM, the data storage structure DS may be a cell capacitor that may store data. The data storage element structure DS may be any kind of capacitor (e.g., a ferroelectric capacitor) used in a one-transistor one-capacitor (1T1C) memory cell, which is a type of memory. However, the invention is not limited thereto. For example, the data storage element structure DS may be any kind of resistor including an MTJ (magnetic tunnel junction), a ferroelectric tunnel junction (FTJ) and combinations thereof used in a one-transistor one-resistor (1T1R) memory cell. For example, the data storage element structure DS may be selected from the group consisting of data storage structures of a phase-change memory (PCM, PRAM, PCRAM, PC-RAM), a resistive memory (RRAM), a magnitoresistive memory (MRAM), a polymer memory (PRAM), a molecular memory, a ferroelectric memory (FeRAM), an ionic memory (PMC), a memristive memory, a spin memory, an oxide memory (such as ReRAM and OxRAM), a conductive bridging random access memory (CBRAM), and combinations thereof.

In the first structure ST1, each first bank area BA1 may include the memory cells (MC in FIG. 3), word lines (WL in FIGS. 2 and 3) electrically connected to the memory cells MC, bit lines (BL in FIGS. 2 and 3) electrically connected to the memory cells MC, and back gate electrodes (BG in FIGS. 2 and 3). As shown in FIG. 3, the word lines WL may extend in a row direction (X-direction) and may be connected to gate terminals of access transistors of the memory cells MC in each row. The bit lines BL may extend in a column direction (Y-direction) and may be connected to drain terminals of the access transistors of the memory cells MC in each column.

Each of the word lines WL may cross the memory cell array regions MCA and the first interface regions IF1 in the first horizontal direction X, and extend into the third interface regions IF3. The word lines WL may be spaced apart from each other in the second horizontal direction Y. Each word line WL of the word lines WL may cross the memory cell array regions MCA and the first interface regions IF1 that are sequentially arranged in the first horizontal direction X, and extend into the third interface regions IF3.

The bit lines BL may cross the memory cell array regions MCA in the second horizontal direction Y, and extend into the second interface region IF2. For example, each bit line of the bit lines BL may cross a corresponding memory cell array region MCA in the second horizontal direction Y, and extend into the second interface regions IF2 adjacent to the corresponding memory cell array region MCA in the second horizontal direction Y.

The back gate electrodes BG may cross the memory cell array regions MCA in the first horizontal direction X, and extend into the first and third interface regions IF1 and IF3 adjacent to the memory cell array regions MCA. For example, each back gate electrode BG of the back gate electrodes BG may cross a corresponding one of memory cell array regions MCA. Each back gate electrode BG of the back gate electrodes BG may extend into the first interface regions IF1 adjacent to the corresponding memory cell array region MCA in the first horizontal direction X, or may extend into the first and third interface regions IF1 and IF3 adjacent to the corresponding memory cell array region MCA in the first horizontal direction X.

The second bank area BA2 in the second structure ST2 may include regions in which circuits used for operations of the memory cells MC are disposed. For example, the second bank area BA2 may include a sense amplifier region in which sense amplifiers for reading data of the memory cells MC are disposed, a sub-word line driver region in which sub-word line drivers capable of activating or deactivating the memory cells MC are disposed, a back gate circuit region for applying a back gate voltage to the back gate electrodes BG, and a peripheral circuitry region for controlling at least one of circuits of the sense amplifier region, the sub-word line driver region, and the back gate circuit region.

The routing interconnection structure (e.g., RTa in FIG. 1B) may be a conductive wire forming signal path including a bit line routing interconnection structure (not shown), a word line routing interconnection structure (not shown), a back gate routing interconnection structure (not shown), and a control routing interconnection structure (not shown). A routing interconnection structure may be referred to as an interconnect.

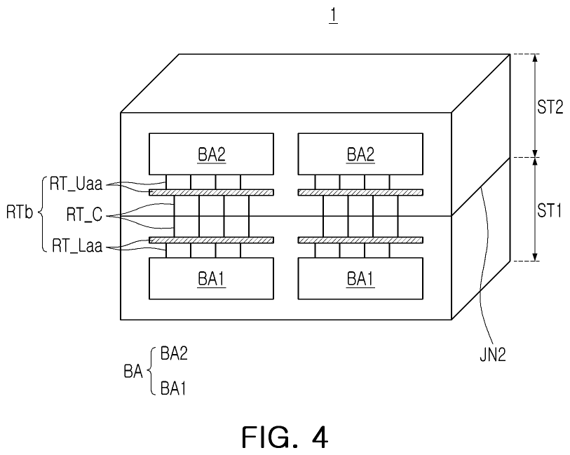

Next, with reference to FIG. 4, another example of the routing interconnection structure (RTa in FIG. 1B) and the bonding surface (JN1 in FIG. 1B) described above will be described. FIG. 4 is a perspective view conceptually illustrating a routing interconnection structure RTb and a bonding surface JN2 according to another example corresponding to the routing interconnection structure RTa and the bonding surface JN1 in FIG. 1B, respectively.

In an embodiment, referring to FIG. 4, the routing interconnection structure RTa in FIG. 1B may be replaced with the routing interconnection structure RTb in which the first bonding pads RT_Lb and the second bonding pads RT_Ub are omitted, and the bonding surface JN1 in FIG. 1B may be replaced with the bonding surface JN2 in which the intermetallic bonding regions JNa are omitted.

The routing interconnection structure RTb may include a first interconnection structure RT_Laa included in the first structure ST1 and electrically connected to the first bank area BA1, a second interconnection structure RT_Uaa included in the second structure ST2 and electrically connected to the second bank area BA2, and a connection structure RT_C extending from the first structure ST1 to the second structure ST2 and electrically connecting the first and second interconnection structures RT_Laa and RT_Uaa. The bonding surface JN2 between the first structure ST1 and the second structure ST2 may result in an interdielectric bonding surface where a dielectric of the first structure ST1 and a dielectric of the second structure ST2 are bonded directly to each other (merge with each other). The connection structure RT_C may include a through-via or a through-connection plug that may penetrate the bonding surface JN2. For example, the bonding surface JN1 in FIG. 1B may be replaced with the bonding surface JN2, in which a through-via or a through-connection plug in the first structure ST1 and those in the second structure ST2 may be connected by other bonding mechanisms than the intermetallic bonding.

Hereinafter, exemplary examples of the first structure ST1 of the semiconductor device 1 will be described with reference to FIGS. 1A, 1B, 2 and 3 together. Hereinafter, exemplary examples of the first structure ST1 of the semiconductor device 1 described in FIGS. 1A, 1B, 2 and 3 will be described, but in embodiments described below, the routing interconnection structure RTa and the bonding surface JN1 described in FIG. 1B may be replaced with the routing interconnection structure RTb and the bonding surface JN2 described in FIG. 4. In addition, the example embodiments described below may be combined with each other to form another example embodiment.

The description will focus on elements disposed in the memory cell array regions MCA and the first, second and third interface regions IF1, IF2 and IF3 in each of the first bank areas BA1 described above.

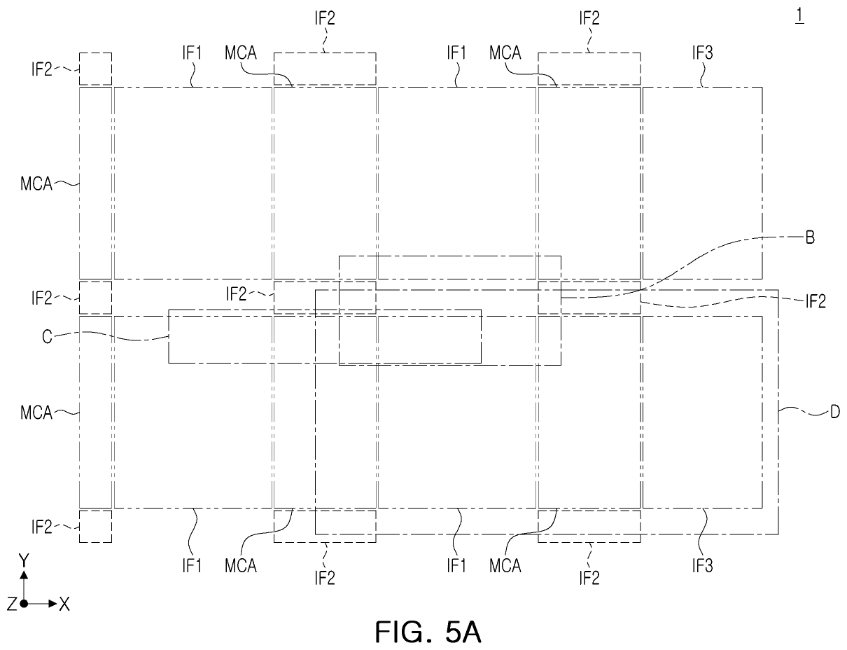

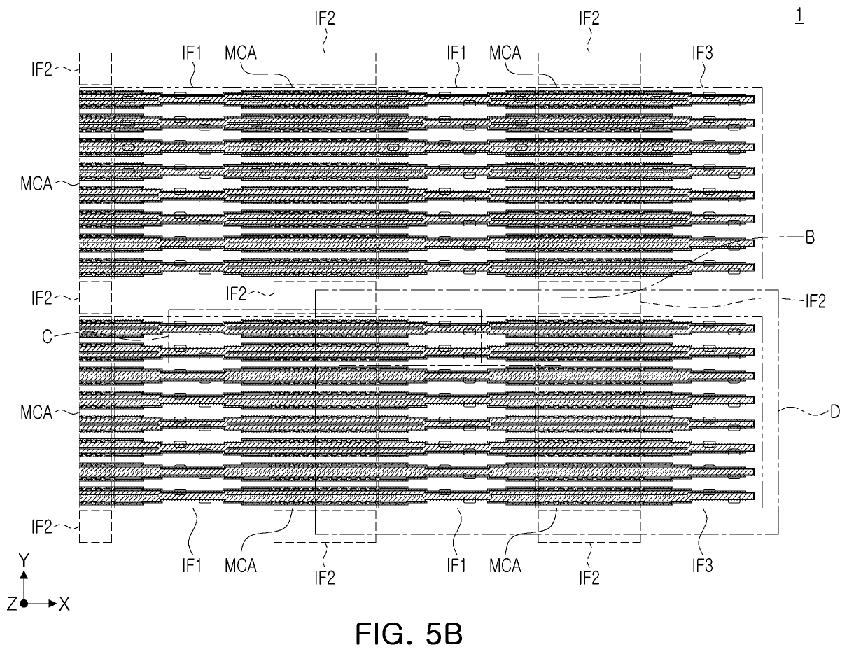

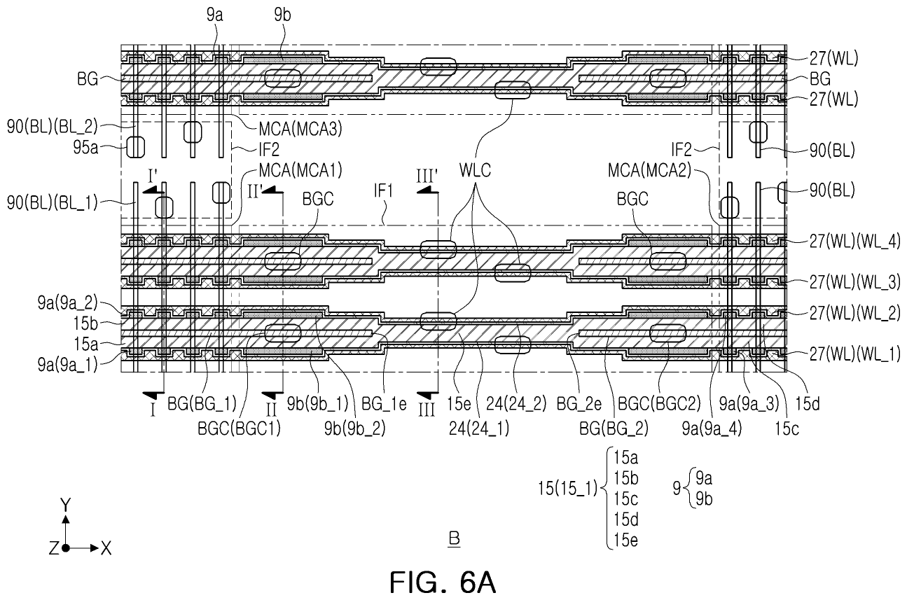

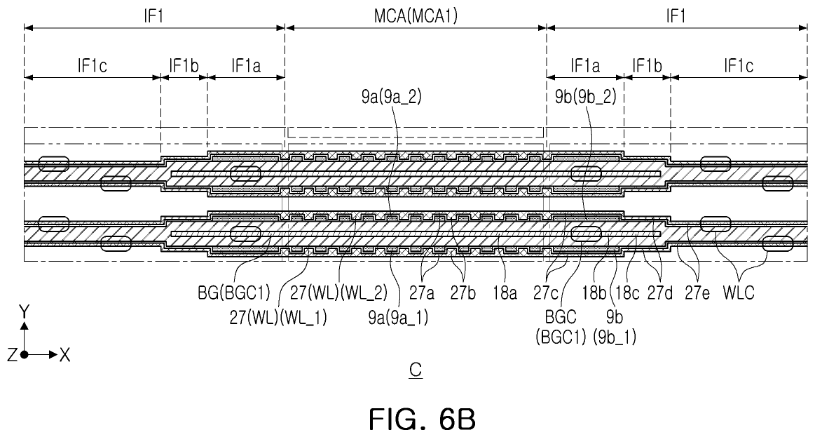

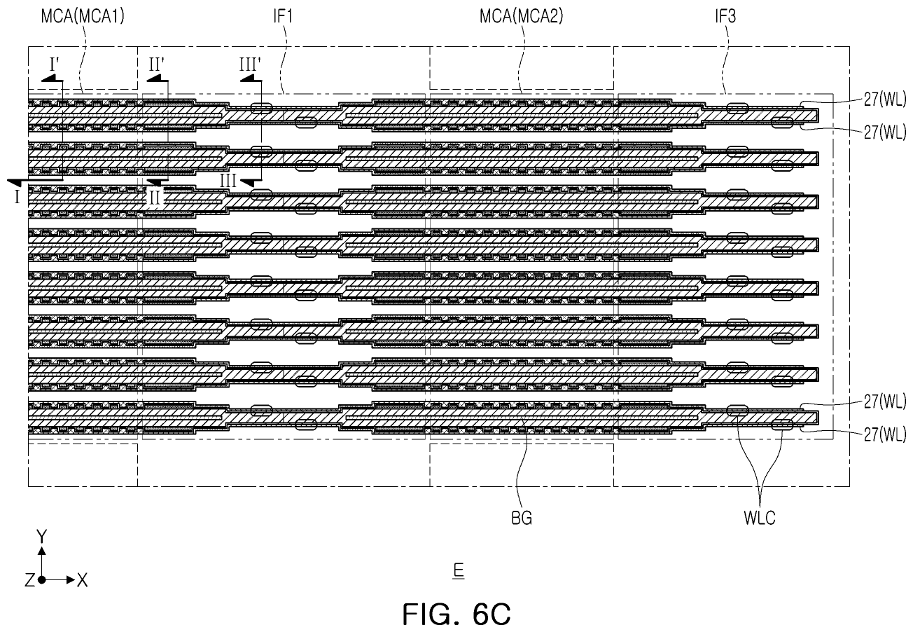

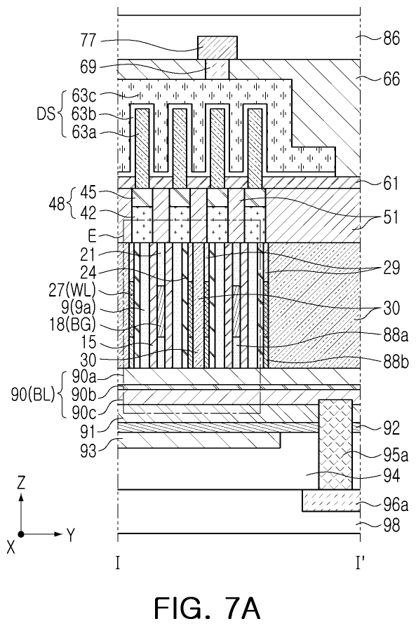

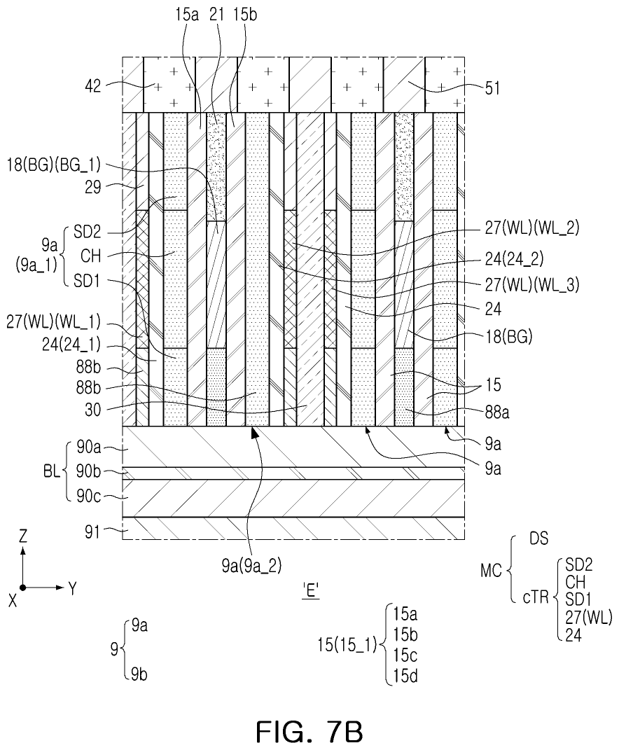

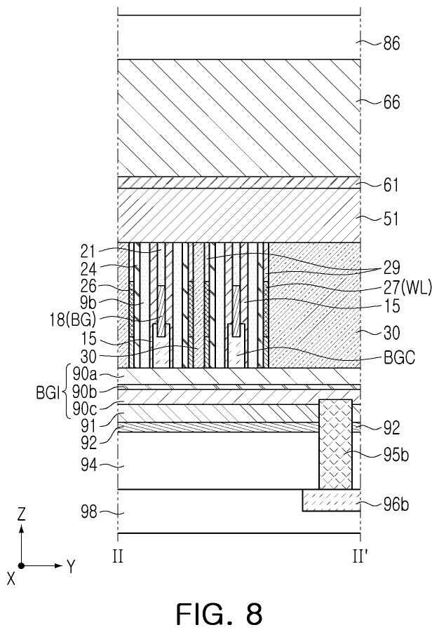

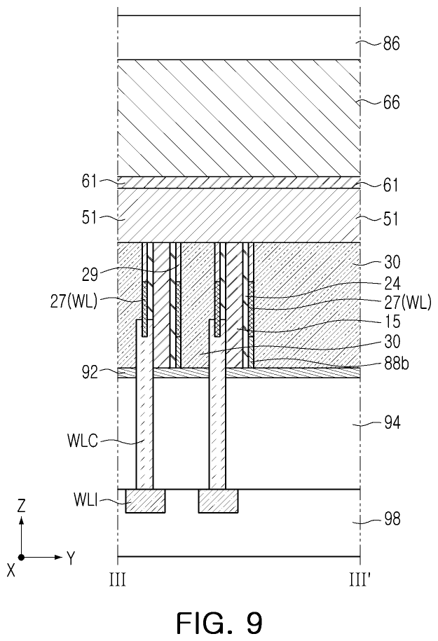

First, with reference to FIGS. 5A, 5B, 6A, 6B, 6C, 7A, 7B, 8 and 9 along with FIGS. 1A, 1B, 2 and 3, an exemplary example of the semiconductor device 1 will be described. FIG. 5A is a plan view illustrating exemplary examples of the memory cell array regions MCA and the first, second and third interface regions IF1, IF2 and IF3. FIG. 5B is a plan view illustrating some of the elements disposed in the memory cell array regions MCA and the first, second and third interface regions IF1, IF2 and IF3 of FIG. 5A. FIG. 6A is a plan view illustrating some of the elements disposed in an area indicated by ‘B’ in FIGS. 5A and 5B. FIG. 6B is a plan view illustrating some of the elements disposed in an area indicated by ‘C’ in FIGS. 5A and 5B. FIG. 6C is a plan view illustrating some of the elements disposed in an area indicated by ‘D’ in FIGS. 5A and 5B. FIG. 7A is a cross-sectional view illustrating an area taken along the line I-I′ in FIG. 6A and FIG. 6C. FIG. 7B is an enlarged partial view of an area indicated by ‘E’ in FIG. 7A. FIG. 8 is a cross-sectional view illustrating an area taken along the line II-II′ of FIG. 6A and FIG. 6C, and FIG. 9 is a cross-sectional view illustrating an area taken along the line III-III′ of FIG. 6A and FIG. 6C.

Referring to FIGS. 5A, 5B, 6A, 6B, 6C, 7A, 7B, 8 and 9 along with FIGS. 1A, 1B, 2 and 3, the semiconductor device 1 may include the memory cell array regions MCA and the first, second and third interface regions IF1, IF2 and IF3 described above.

Hereinafter, among the memory cell array regions MCA, the description will be focused on a first memory cell array region MCA1 and a second memory cell array region MCA2 adjacent to each other in the first horizontal direction X, and the first memory cell array region MCA1 and a third memory cell array region MCA3 adjacent to each other in the second horizontal direction Y, while among the interface regions IF1, IF2 and IF3, the description will be focused on the first interface region IF1 disposed between the first memory cell array region MCA1 and the second memory cell array region MCA2, the second interface region IF2 disposed between the first memory cell array region MCA1 and the third memory cell array region MCA3, and the third interface region IF3 adjacent to the second memory cell array region MCA2.

The semiconductor device 1 may further include cell gate electrodes 27, back gate electrodes 18, back gate dielectric layers 15, active patterns 9, and cell gate dielectric layers 24.

The cell gate electrodes 27 may be parts of the word lines WL described above (e.g., cell gate electrodes of a row of memory cells may form parts of a single electrical node corresponding to a word line). The cell gate electrodes 27 may include a first word line WL_1 and a second word line WL_2 spaced apart from and adjacent to each other in the second horizontal direction Y. The first word line WL_1 and the second word line WL_2 may cross the first memory cell array region MCA1, the first interface region IF1 and the second memory cell array region MCA2. The back gate electrodes 18 may be the back gate electrodes BG described above.

A minimum distance between the first and second word lines WL_1 and WL_2 in the first memory cell array region MCA1 may be greater than a minimum distance between the first and second word lines WL_1 and WL_2 in the first interface region IF1.

The first and second word lines WL_1 and WL_2 may include first portions (27a in FIG. 6B) facing each other in the first memory cell array region MCA1, second portions (27b in FIG. 6B) facing each other in the first memory cell array region MCA1, third portions (27c in FIG. 6B) facing each other in the first interface region IF1, fourth portions (27d in FIG. 6B) facing each other in the first interface region IF1, and fifth portions (27e in FIG. 6B) facing each other in the first interface region IF1.

The first portions (27a in FIG. 6B) may be the first portion 27a of the first word line WL_1 and the first portion 27a of the second word line WL_2, the second portions (27b in FIG. 6B) may be the second portion 27b of the first word line WL_1 and the second portion 27b of the second word line WL_2, the third portions (27c in FIG. 6B) may be the third portion 27c of the first word line WL_1 and the third portion 27c of the second word line WL_2, the fourth portions (27d in FIG. 6B) may be the fourth portion 27d of the first word line WL_1 and the fourth portion 27d of the second word line WL_2, and the fifth portions (27e in FIG. 6B) may be the fifth portion 27e of the first word line WL_1 and the fifth portion 27e of the second word line WL_2.

The active patterns 9 may have symmetry in their arrangement in a plan view. A first cell active pattern 9a_1 and a second cell active pattern 9a_2 facing each other along an imaginary plane extending in the first horizontal direction X and in a vertical direction Z, and the first and second cell active patterns 9a_1 and 9a_2 may be disposed between the first portions 27a. The first cell active pattern 9a_1 and the second cell active pattern 9a_2 may be arranged symmetrically with respect to the imaginary plane in a plan view.

The second portion 27b of the first word line WL_1 may be disposed between two first cell active patterns 9a_1 adjacent to each other among the first cell active patterns 9a_1, and the second portion 27b of the second word line WL_2 may be disposed between two second cell active patterns 9a_2 adjacent to each other among the second cell active patterns 9a_2.

A first dummy active pattern 9b_1 and a second dummy active pattern 9b_2 may be disposed between the third portions 27c. A first back gate electrode BG_1 of the back gate electrodes BG may be disposed between the first portions 27a, between the second portions 27b, between the third portions 27c, or the fourth portions 27d, and may not be disposed between the fifth portions 27e.

A spacing between the first portions 27a may be greater than a spacing between the second portions 27b. A spacing between the third portions 27c, a spacing between the fourth portions 27d, and a spacing between the fifth portions 27e may be different from each other.

The spacing between the third portions 27c may be greater than the spacing between the fourth portions 27d.

The spacing between the fourth portions 27d may be greater than the spacing between the fifth portions 27e.

The spacing between the fifth portions 27e may be less than the spacing between the second portions 27b.

The spacing between the third portions 27c may be substantially the same as the spacing between the first portions 27a.

The spacing between the fourth portions 27d may be substantially the same as the spacing between the second portions 27b.

A minimum spacing between the first and second word lines WL_1 and WL_2 in the first memory cell array region MCA1 may be the spacing between the second portions 27b.

A maximum spacing between the first and second word lines WL_1 and WL_2 in the first memory cell array region MCA1 may be the spacing between the first portions 27a.

A minimum distance between the first and second word lines WL_1 and WL_2 in the first interface region IF1 may be the spacing between the fifth portions 27e.

A maximum distance between the first and second word lines WL_1 and WL_2 in the first interface region IF1 may be the spacing between the third portions 27c.

The maximum distance between the first and second word lines WL_1 and WL_2 in the first memory cell array region MCA1 may be substantially equal to the maximum distance between the first and second word lines WL_1 and WL_2 in the first interface region IF1.

The first back gate electrode BG_1 may include a first back gate portion 18a passing between the first portions 27a and between the second portions 27b in the first memory cell array region MCA1, a second back gate portion 18b disposed between the third portions 27c in the first interface region IF1, and a third back gate portion 18c disposed between the fourth portions 27d in the first interface region IF1. The first back gate electrode BG_1 may not be disposed between the fifth portions 27e in the first interface region IF1.

The first back gate portion 18a, the second back gate portion 18b and the third back gate portion 18c may have substantially the same width.

The first interface region IF1 may include a first region IF1a in which the third portions 27c and the second back gate portion 18b are disposed, a second region IF1b in which the fourth portions 27d and the third back gate portion 18c are disposed, and a middle region IFc in which the fifth portions 27e are disposed.

In the first interface region IF1, the first region IF1a may be adjacent to the memory cell array region MCA, and the second region IF1b may be disposed between the first region IF1a and the middle region IFc.

In the first interface region IF1, a length of the middle region IF1c in the first horizontal direction X may be greater than a length of each of the first region IF1a and the second region IF1b in the first horizontal direction X.

In the first interface region IF1, the length of the first region IF1a in the first horizontal direction X may be greater than the length of the second region IF1b in the first horizontal direction X.

For example, in a plan view, the first and second word lines WL_1 and WL_2 may have a wavy shape and may be arranged symmetrically with respect to the imaginary plane, and corresponding segments (or portions) 27a, 27b, 27c, 27d and 27e of the pair of the first and second word lines WL_1 and WL_2 may face each other in each of distinct regions including regions MCA1, IF1a, IF1b and IF1c. Accordingly, the minimum facing distance (or separation distance in a plan view) in a region may be different from that in other regions. The imaginary plane may extend along a corresponding one of the back gate electrode BG, and corresponding one of the back gate electrode BG may be disposed between the first and second word lines WL_1 and WL_2.

The cell gate electrodes 27 may be formed of a conductive material. For example, each of the cell gate electrodes 27 may be made of doped polysilicon, Al, Cu, Ti, Ta, Ru, W, Mo, Pt, Ni, Co, TiN, TaN, WN, NbN, TiAl, TiAIN, TiSi, TiSiN, TaSi, TaSiN, RuTiN, NiSi, CoSi or a combination thereof, but is not limited thereto. Each of the cell gate electrodes 27 may include a single layer or multiple layers of the aforementioned conductive materials.

The back gate electrodes 18 may include the first back gate electrode BG_1 crossing the first memory cell array region MCA1 and a second back gate electrode BG_2 crossing the second memory cell array region MCA2. The first back gate electrode BG_1 may have a first end portion BG_1e positioned in the first interface region IF1, and the second back gate electrode BG_2 may have a second end portion BG_2e positioned in the first interface region IF1. The first end portion BG_1e of the first back gate electrode BG_1 may face the second end portion BG_2e of the second back gate electrode BG_2 in the first horizontal direction X. At least a portion of each of the back gate electrodes 18 may be disposed on the same vertical level as the cell gate electrodes 27. At least a portion of each of the cell gate electrodes 27 may be disposed on the same vertical level as the back gate electrodes 18.

The back gate electrodes 18 may be formed of a conductive material. For example, each of the back gate electrodes 18 may be made of doped polysilicon, Al, Cu, Ti, Ta, Ru, W, Mo, Pt, Ni, Co, TiN, TaN, WN, NON, TiAl, TiAIN, TiSi, TiSiN, TaSi, TaSiN, RuTiN, NiSi, CoSi or a combination thereof, but is not limited thereto. Each of the back gate electrodes 18 may include a single layer or multiple layers of the aforementioned conductive materials.

The back gate dielectric layers 15 may be in contact with the back gate electrodes 18. The back gate dielectric layers 15 may surround side surfaces of the back gate electrodes 18. The back gate dielectric layers 15 may extend in the first horizontal direction X, cross the memory cell array regions MCA and the first interface regions IF1, and extend into the third interface regions IF3.

The back gate dielectric layers 15 may be arranged symmetrically with respect to the imaginary plane in a plan view. The back gate dielectric layers 15 may include a first back gate dielectric layer 15_1 disposed between the first and second word lines.

The first back gate dielectric layer 15_1 may include a first portion 15a disposed between the first word line WL_1 and the first back gate electrode BG_1 and a second portion 15b disposed between the second word line WL_2 and the first back gate electrode BG_1, in the first memory cell array region MCA1.

The first back gate dielectric layer 15_1 may include a third portion 15c disposed between the first word line WL_1 and the second back gate electrode BG_2 and a fourth portion 15d disposed between the second word line WL_2 and the second back gate electrode BG_2, in the second memory cell array region MCA2.

The first back gate dielectric layer 15_1 may further include a fifth portion 15e covering the first end portion BG_1e of the first back gate electrode BG_1 and the second end portion BG_2e of the second back gate electrode BG_2 in the first interface region IF1.

The active patterns 9 may include a semiconductor material that may be used as a channel region of a transistor. For example, the active patterns 9 may include a semiconductor material such as single crystal silicon. The active patterns 9 may be disposed on the same level as each other. The active patterns 9 may include a semiconductor material such as an oxide semiconductor.

The active patterns 9 may include cell active patterns 9a disposed in the memory cell array regions MCA, and dummy active patterns 9b disposed in the first and third interface regions IF1 and IF3. Each of the active patterns 9 may have an elongated bar shape, an oval shape, or a bar shape close to an oval shape in the first horizontal direction X. The cell active patterns 9a may be spaced apart from each other in the first horizontal direction X and the second horizontal direction Y in the memory cell array regions MCA. In the first horizontal direction X, a length of each of the dummy active patterns 9b may be greater than a length of each of the cell active patterns 9a. In the second horizontal direction Y, a width of each of the dummy active patterns 9b may be substantially the same as a width of each of the cell active patterns 9a. The dummy active patterns 9b may include dummy active patterns disposed adjacent to the cell active patterns 9a of the first memory cell array region MCA1 and dummy active patterns disposed adjacent to the cell active patterns 9a of the second memory cell array region MCA2 in the first interface region IF1.

Each of the cell active patterns 9a may include a first source/drain region (SD1 in FIG. 7B), a second source/drain region (SD2 in FIG. 7B) disposed on a level different from that of the first source/drain region SD1, and a channel region (CH in FIG. 7B) between the first and second source/drain regions SD1 and SD2.

In an example, the second source/drain region SD2 may be disposed on the first source/drain region SD1.

The cell gate dielectric layers 24 may surround side surfaces of the back gate dielectric layers 15, and the active patterns 9 may be disposed between the cell gate dielectric layers 24 and the back gate dielectric layers 15.

Each of the active patterns 9 may have side surfaces opposing each other in the first horizontal direction X and side surfaces opposing each other in the second horizontal direction Y. The side surfaces of the active patterns 9 opposing each other in the first horizontal direction X may be covered by the cell gate dielectric layers 24. Among the side surfaces of the active patterns 9 opposing each other in the second horizontal direction Y, the side surfaces facing the back gate electrodes 18 may be covered by the back gate dielectric layers 15, and the side surfaces facing the cell gate electrodes 27 may be covered by the cell gate dielectric layers 24. The cell gate dielectric layers 24 may be disposed between the cell gate electrodes 27 and the active patterns 9.

The cell gate dielectric layers 24 may include a first cell gate dielectric layer 24_1 in contact with the first word line WL_1 and a second cell gate dielectric layer 24_2 in contact with the second word line WL_2. In a plan view, the first cell gate dielectric layer 24_1 and the second cell gate dielectric layer 24_2 the first and second word lines WL_1 and WL_2 may have a wavy shape and may be arranged symmetrically with respect to the imaginary plane.

The cell active patterns 9a may include the first cell active patterns 9a_1 disposed between the first word line WL_1 and the first back gate dielectric layer 15_1 in the first memory cell array region MCA1, the second cell active patterns 9a_2 disposed between the second word line WL_2 and the first back gate dielectric layer 15_1 in the first memory cell array region MCA1, third cell active patterns 9a_3 disposed between the first word line WL_1 and the first back gate dielectric layer 15_1 in the second memory cell array region MCA2, and fourth cell active patterns 9a_4 disposed between the second word line WL_2 and the first back gate dielectric layer 15_1 in the second memory cell array region MCA2.

The first cell active patterns 9a_1 may be disposed between the first cell gate dielectric layer 24_1 and the first back gate dielectric layer 15_1 in the first memory cell array region MCA1, and the second cell active patterns 9a_2 may be disposed between the second cell gate dielectric layer 24_2 and the first back gate dielectric layer 15_1 in the first memory cell array region MCA1.

The first cell gate dielectric layer 24_1 may extend between the first cell active patterns 9a_1 adjacent to each other in the first horizontal direction X from portions disposed between the first cell active patterns 9a_1 and the first word line WL_1, and the second cell gate dielectric layer 24_2 may extend between the second cell active patterns 9a_2 adjacent to each other in the first horizontal direction X from portions disposed between the first second active patterns 9a_2 and the second word line WL_2.

The dummy active patterns 9b may include the first dummy active pattern 9b_1 disposed between the first word line WL_1 and the first back gate dielectric layer 15_1 in the first interface region IF1, and the second dummy active pattern 9b_2 disposed between the second word line WL_2 and the first back gate dielectric layer 15_1. The first and second dummy active patterns 9b_1 and 9b_2 may face each other in the second horizontal direction Y, and in the first horizontal direction X, a length of each of the first and second dummy active patterns 9b_1 and 9b_2 may be greater than a length of each of the first and second cell active patterns 9a_1 and 9a_2.

In embodiments, the channel regions CH of the cell transistors cTR may be floating bodies, and the back gate electrodes 18 facing the channel regions CH may suppress or prevent the performance of the cell transistors cTR from being degraded due to the floating body effect.

Each of the cell transistors cTR described above may include the first source/drain region SD1, the second source/drain region SD2, and the channel region CH disposed in a corresponding cell active pattern 9a among the cell active patterns 9a, the cell gate electrode 27 facing the channel region CH, and the cell gate dielectric layer 24 between the channel region CH and the cell gate electrode 27. In each of the cell transistors cTR, the cell gate electrode 27 may have a side surface facing a side surface of the channel region CH.

The semiconductor device 1 may further include first insulating back gate capping patterns 21 on the back gate electrodes 18 and second insulating back gate capping patterns 88a below the back gate electrodes 18.

The back gate dielectric layers 15 may extend upwardly and downwardly from a portion disposed between the back gate electrodes 18 and the active patterns 9. Accordingly, the back gate dielectric layers 15 may be disposed between the back gate electrodes 18 and the active patterns 9, between the first back gate capping patterns 21 and the active patterns 9, and between the second back gate capping patterns 88a and the active patterns 9.

The semiconductor device 1 may further include first insulating gate capping patterns 29 disposed on the cell gate electrodes 27, and second insulating gate capping patterns 88b disposed below the cell gate electrodes 27.

The cell gate dielectric layers 24 may extend upwardly and downwardly from a portion disposed between the cell gate electrodes 27 and the active patterns 9. Accordingly, the cell gate dielectric layers 24 may be disposed between the cell gate electrodes 27 and the active patterns 9, between the first gate capping patterns 29 and the active patterns 9, and between the second gate capping patterns 88b and the active patterns 9.

The semiconductor device 1 may further include an insulating pattern 30 disposed between the adjacent cell gate electrodes 27, between the first gate capping patterns 29, and between the second gate capping patterns 88b. For example, the cell gate electrodes 27 may include the first word line WL_1, the second word line WL_2, a third word line WL_3, and a fourth word line WL_4 that are arranged in sequence in the second horizontal direction Y, and the back gate electrodes 18 may be disposed between the first and second word lines WL_1 and WL_2 and between the third and fourth word lines WL_3 and WL_4, while the back gate electrodes 18 may not be disposed between the second and third word lines WL_2 and WL_3, and the insulating pattern 30 may be disposed therebetween.

The semiconductor device 1 may include bit lines 90. The bit lines 90 may be the bit lines BL described above. The bit lines 90 may be disposed below the cell active patterns 9a, and may be connected to lower surfaces of the cell active patterns 9a. The bit lines 90 may be electrically connected to the first source/drain regions SD1 of the cell active patterns 9a. The bit line 90 may be parts of the bit lines BL described above with reference to FIGS. 2 and 3.

The bit lines 90 may include first bit lines BL_1 crossing the first memory cell array region MCA1 and extending into the second interface region IF2 in the second horizontal direction Y, and second bit lines BL_2 crossing the third memory cell array region MCA3 and extending into the second interface region IF2 in the second horizontal direction Y. In the second interface region IF2, end portions of the first bit lines BL_1 and end portions of the second bit lines BL_2 may face each other.

A width of the first interface region IF1 in the first horizontal direction X may be greater than a width of the second interface region IF2 in the second horizontal direction Y. A distance between the first memory cell array region MCA1 and the second memory cell array region MCA2 may be greater than a distance of the first memory cell array region MCA1 and the third memory cell array region MCA3.

The semiconductor device 1 may further include back gate contact plugs BGC and back gate interconnection structures BGI.

The back gate contact plugs BGC may be connected to the back gate electrodes 18. The back gate contact plugs BGC may be connected to a region adjacent to the memory cell array region MCA, such as the second back gate portion 18b disposed in the first region IF1a of the first interface region IF1. For example, a first back gate contact plug BGC1 of the back gate contact plugs BGC connected to the first back gate electrode (BG_1 in FIGS. 6A and 6B) may be connected to a portion of the first back gate electrode BG_1 located between the first dummy active pattern 9b_1 and the second dummy active pattern 9b_2, e.g., the second back gate portion 18b.

The back gate interconnection structures BGI may be connected to the dummy active patterns 9b below the dummy active patterns 9b. The back gate interconnection structures BGI may be disposed on the same level as the bit lines BL, and may be formed of the same material as the bit lines BL.

Each of the bit lines 90 and the back gate interconnection structures BGI may include a first material layer 90a, a second material layer 90b below the first material layer 90a, and a third material layer 90c on the second material layer 90b. The first material layer 90a may include at least one of doped silicon, doped germanium or doped silicon-germanium. The second material layer 90b may include at least one of a metal-semiconductor compound layer or a metal nitride. The third material layer 90c may include at least one of a metal or a metal nitride.

Each of the back gate interconnection structures BGI may extend in the second horizontal direction Y. A width of each of the back gate interconnection structures BGI may be greater than a width of each of the bit lines BL.

The back gate contact plugs BGC may be disposed between the back gate interconnection structures BGI and the back gate electrodes 18. The back gate contact plugs BGC may be connected to lower surfaces the back gate electrodes 18 and side surfaces of lower regions thereof.

The semiconductor device 1 may further include insulating capping patterns 91 disposed below the bit lines 90 and the back gate interconnection structures BGI, and aligned with the bit lines 90 and the back gate interconnection structures BGI. The capping patterns 91 may be formed of an insulating material.

The semiconductor device 1 may further include an insulating liner 92 covering a lower surface of a structure including the bit lines 90, the back gate interconnect structures BGI and the bit line capping patterns 91.

The semiconductor device 1 may further include a bit line shield pattern 93 disposed between the bit lines 90 below the insulating liner 92 and extending below lower surfaces of the capping patterns 91 disposed below the bit lines 90. The bit line shield pattern 93 may be formed of a conductive material. Since the bit line shield pattern 93 may reduce parasitic capacitance between the bit lines 90, it may prevent a signal transmission speed of the bit lines 90 from decreasing.

The semiconductor device 1 may further include a first lower insulating layer 94 disposed below the bit line shield pattern 93 and the insulating liner 92, and a second lower insulating layer 98 disposed below the first lower insulating layer 94.

The semiconductor device 1 may further include rear contact plugs 95a and 95b disposed in the second interface region IF2. The rear contact plugs 95a and 95b may penetrate the first lower insulating layer 94, the insulating liner 92 and the capping pattern 91. The rear contact plugs 95a and 95b may include first rear contact plugs 95a connected to the bit lines 90 and second rear contact plugs 95b connected to the back gate interconnection structures BGI.

The semiconductor device 1 may further include word line contact plugs WLC connected to the word lines 27 in the first and third interface regions IF1 and IF3. For example, each word line WL crossing each memory cell array region MCA1 of the memory cell array regions MCA may be connected to the word line contact plugs WLC disposed in the first interface regions IF1 disposed on both sides of each memory cell array region MCA1 or connected to the word line contact plugs WLC disposed in the first and third interface regions IF1 and IF3 disposed on both sides of each memory cell array region MCA1. For example, each word line WL crossing a memory cell array region MCA1 may be connected to two word line contact plugs WLC disposed on both sides of each memory cell array region MCA1.

The word line contact plugs WLC may be in contact with lower surfaces of the word lines 27 and side surfaces of lower regions thereof in the first and third interface regions IF1 and IF3. The word line contact plugs WLC may extend downward from portions in contact with the word lines 27 and penetrate the insulating liner 92 and the first lower insulating layer 94.

The semiconductor device 1 may further include rear interconnections 96a, 96b and WLI disposed below the first lower insulating layer 94. The rear interconnections 96a, 96b and WLI may include first rear interconnections 96a connected to the first rear contact plugs 95a, second rear interconnections 96b connected to the second rear contact plugs 95b, and third rear interconnections WLI connected to the word line contact plugs WLC. The second lower insulating layer 98 may cover the rear interconnections 96a, 96b and WLI.

The semiconductor device 1 may further include contact structures 48 and an insulating structure 51. The contact structures 48 may be disposed on the cell active patterns 9a. The contact structures 48 may be connected to the cell active patterns 9a. For example, the contact structures 48 may be electrically connected to the second source/drain regions SD2.

Each of the contact structures 48 may include a first material layer 42 and a second material layer 45 on the first material layer 42. The first material layer 42 may include a material such as doped silicon. The second material layer 45 may include one of a metal, a metal nitride or a metal-semiconductor compound. The insulating structure 51 may surround side surfaces of the contact structures 48.

The semiconductor device 1 may further include an insulating etch-stop layer 61 disposed on the contact structures 48 and the insulating structure 51.

The data storage structure DS described above may include first electrodes 63a penetrating the insulating etch-stop layer 61, connected to the contact structures 48 and extending upward, a dielectric layer 63b covering the first electrodes 63a and the etch-stop layer 61, and a second electrode 63c covering the dielectric layer 63b. The data storage structure DS may be cell capacitors capable of storing data in a memory, such as a DRAM.

As described above, each of the memory cells MC may include the data storage structure DS and the cell transistor cTR.

The contact structures 48 may be disposed between the data storage structure DS and the cell transistors cTR. The data storage structure DS may be electrically connected to the cell transistors cTR by the contact structures 48.

The semiconductor device 1 may further include a first upper insulating layer 66 on the data storage structure DS and the insulating etch-stop layer 61, an upper contact plug 69 penetrating the first upper insulating layer 66 and connected to the second electrode 63c, an upper interconnection 77 connected to the upper contact plug 69 on the first upper insulating layer 66, and a second upper insulating layer 86 covering the first upper insulating layer 66 and the upper interconnection 77.

In embodiments, in each of the bank areas BA1, each of the word lines WL may cross the plurality of memory cell array regions MCA arranged in the first horizontal direction and the first interface regions IF1 between the plurality of memory cell array regions MCA. Accordingly, since a space occupied by the first interface regions IF1 in the bank areas BA1 may be minimized, the integration of the semiconductor device 1 may be increased.

In embodiments, each word line WL crossing each memory cell array region MCA1 may be connected to two word line contact plugs WLC disposed interface regions located on both sides of the memory cell array region MCA1. The word line contact plugs WLC may be a portion of the routing interconnection structure (RTa in FIG. 1B or FIG. 4) described above. Therefore, since each word line WL crossing each memory cell array region MCA1 is directly electrically connected to the two word line contact plugs WLC arranged on both sides, a transmission speed of a signal applied to the entire word line WL may be increased. Therefore, the performance of the semiconductor device 1 may be improved.

Hereinafter, various example embodiments of the semiconductor device 1 will be described. The various example embodiments described below and the previously described embodiments may be combined to form another example embodiment. Hereinafter, the elements described above may be directly cited without a separate detailed description, or descriptions thereof may be omitted. Additionally, the elements that may be modified or replaced as described below are described with reference to the drawings below, but the elements that may be modified, replaced, or added may be combined with each other or with the elements described above to form a semiconductor device according to an example embodiment of the present disclosure. Additionally, in the case in which the elements described above are provided in plural, the following description will focus on the case in which the number of elements described above is one.

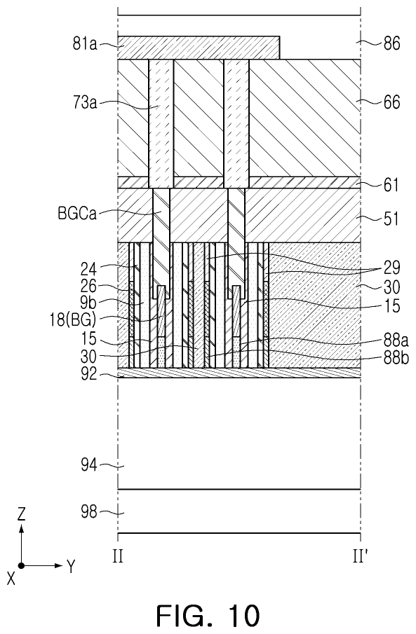

With reference to FIG. 10, an example embodiment of the semiconductor device 1 will be described. FIG. 10 is a cross-sectional view illustrating an element modified from the II-II′ cross-sectional structure of FIG. 8 described above.

In an embodiment, referring to FIG. 10, the back gate contact plug (BGC in FIG. 8) described above may be replaced with a back gate contact plug BGCa in contact with an upper surface of the back gate electrode 18. The back gate contact plug BGCa may be in contact with an upper surface of the back gate electrode 18 and side surfaces of an upper region thereof. The back gate contact plug BGCa may be in contact with the back gate electrode 18 and extend upward to penetrate the insulating structure 51.

The second rear interconnection 96b described above may be replaced with a back gate upper contact plug 73a penetrating the first upper insulating layer 66 and connected to the back gate contact plug BGCa, and a back gate upper interconnection 81a connected to the back gate upper contact plug 73a on the first upper insulating layer 66.

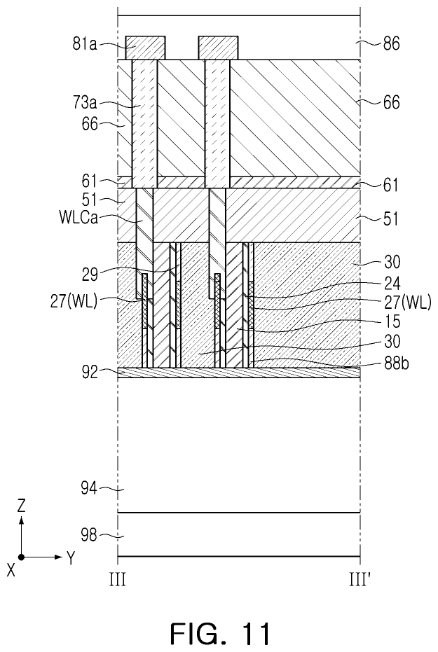

With reference to FIG. 11, an example embodiment of the semiconductor device 1 will be described. FIG. 11 is a cross-sectional view illustrating an element modified from the III-III′ cross-sectional structure of FIG. 9 described above.

In an embodiment, referring to FIG. 11, the word line contact plug (WLC in FIG. 9) described above may be replaced with a word line contact plug WLCa in contact with an upper surface of the cell gate electrode 27. The word line contact plug WLCa may be in contact with an upper surface of the cell gate electrode 27 and side surfaces of an upper region thereof. The word line contact plug WLCa may be in contact with the cell gate electrode 27 and extend upward to penetrate the insulating structure 51.

The third backside interconnection WLI described above may be replaced with a word line upper contact plug 73b penetrating the first upper insulating layer 66 and connected to the word line contact plug WLCa, and a word line upper interconnection 81b connected to the word line upper contact plug 73b on the first upper insulating layer 66.

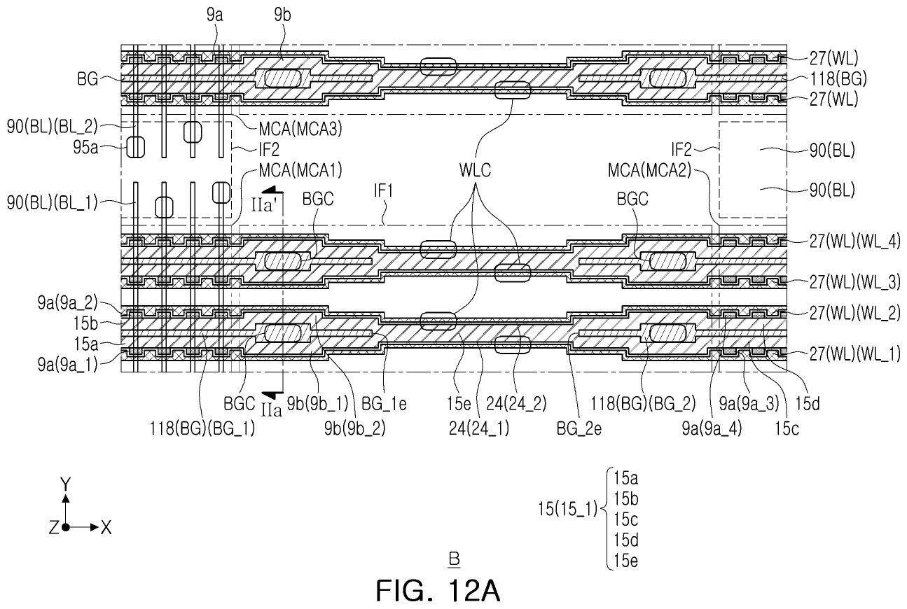

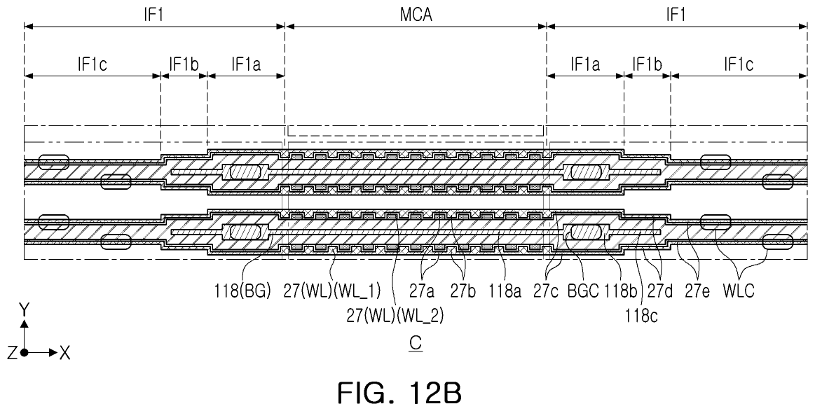

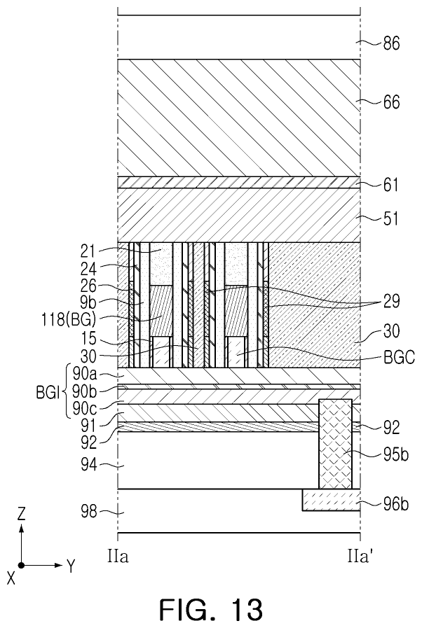

With reference to FIGS. 12A, 12B and 13, an example embodiment of the semiconductor device 1 will be described. FIG. 12A is a plan view illustrating an element modified from the planar structure in FIG. 6A described above, FIG. 12B is a plan view illustrating an element modified from the planar structure in FIG. 6B described above, and FIG. 13 is a cross-sectional view taken along line IIa-IIa′ in FIG. 12A, which may illustrate an element modified from the II-II′ cross-sectional structure of FIG. 8.

In an embodiment, referring to FIGS. 12A, 12B and 13, the dummy active patterns 9b described above may be removed, and the back gate dielectric layers 15 and the back gate electrodes 18 described above may extend into a space in which the dummy active patterns 9b are removed. Accordingly, the back gate dielectric layers 15 and the back gate electrodes 18 described above may be replaced with back gate dielectric layers 115 and back gate electrodes 118 including a portion disposed in the space in which the dummy active patterns 9b are removed.

As described above, the first back gate electrode BG_1 may include a first back gate portion 118a passing between the first portions 27a and between the second portions 27b in the first memory cell array region MCA1, a second back gate portion 118b disposed between the third portions 27c in the first interface region IF1, and a third back gate portion 118c disposed between the fourth portions 27d in the first interface region IF1.

A width of the second back gate portion 118b may be greater than a width of each of the first back gate portion 118a and the third back gate portion 118c.

The first back gate portion 118a and the third back gate portion 118c may have substantially the same width.

The back gate contact plug BGC described above may be in contact with and connected to the second back gate portion 118b. As the width of the second back gate portion 118b increases, the back gate contact plug BGC may be stably connected to the second back gate portion 118b.

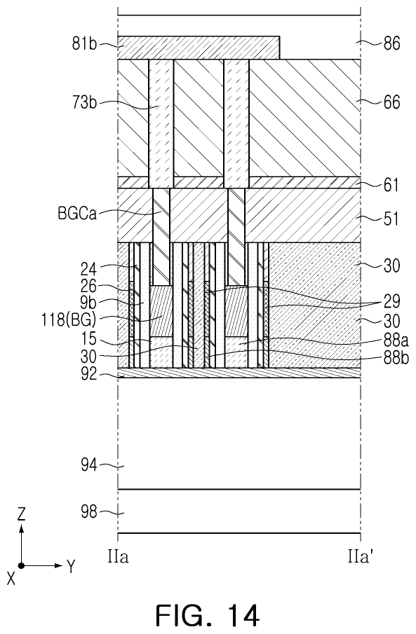

With reference to FIG. 14, an example embodiment of the semiconductor device 1 will be described. FIG. 14 is a cross-sectional view illustrating an element modified from the IIa-IIa′ cross-sectional structure of FIG. 13 described above.

In an embodiment, referring to FIG. 14, the back gate contact plug (BGC in FIG. 13) described above may be replaced with a back gate contact plug BGCa in contact with an upper surface of the back gate electrode 118. The back gate contact plug BGCa may be in contact with the back gate electrode 118 and extend upward to penetrate the insulating structure 51. The second rear interconnection 96b described above may be replaced with a back gate upper contact plug 73a penetrating the first upper insulating layer 66 and connected to the back gate contact plug BGCa, and a back gate upper interconnection 81a connected to the back gate upper contact plug 73a on the first upper insulating layer 66.

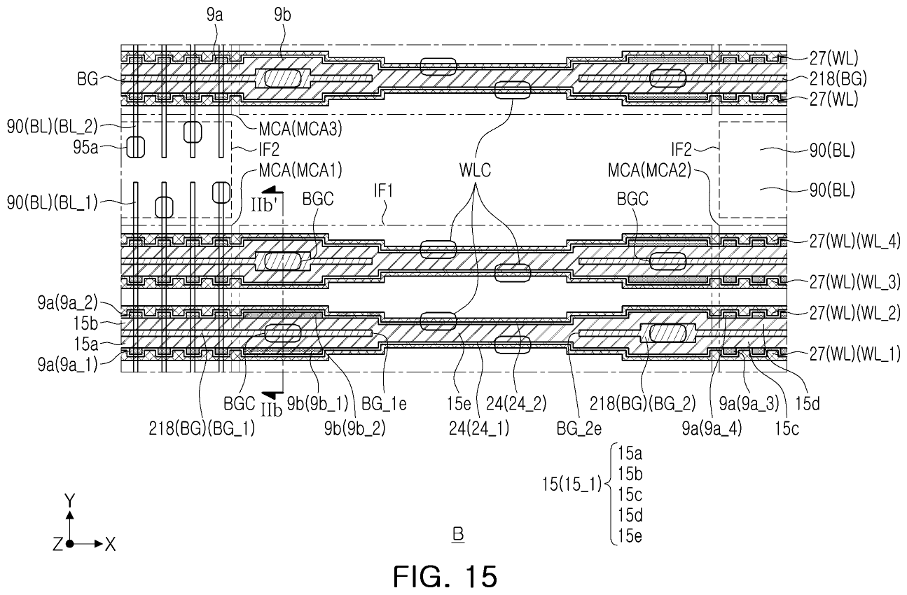

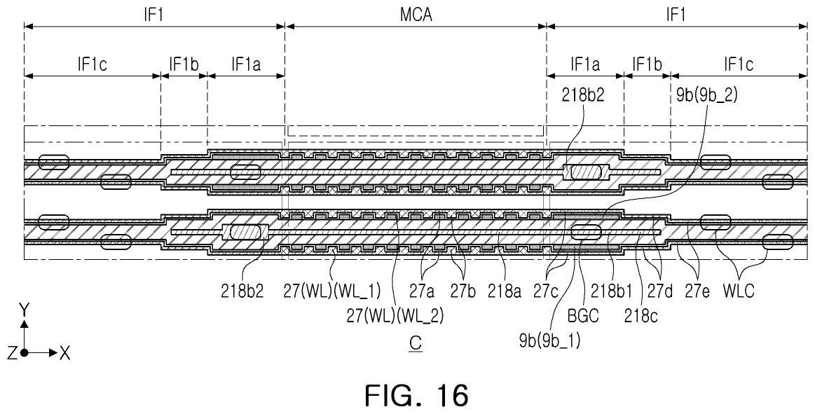

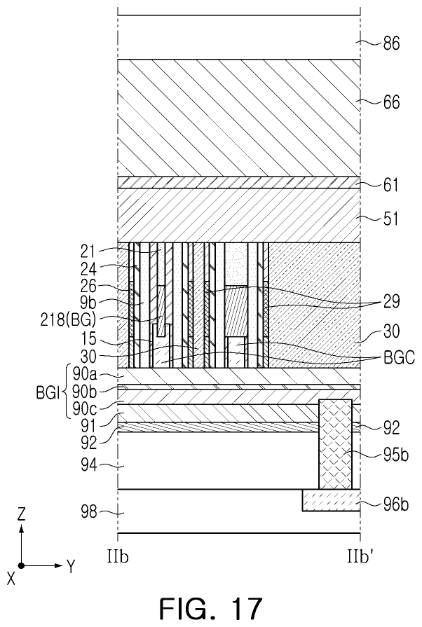

With reference to FIGS. 15, 16 and 17, an example embodiment of the semiconductor device 1 will be described. FIG. 15 is a plan view illustrating an element modified from the planar structure of FIG. 12A described above, FIG. 16 is a plan view illustrating an element modified from the planar structure of FIG. 12B described above, and FIG. 17 is a cross-sectional view taken along line IIb-IIb′ in FIG. 16, which may illustrate an element modified from the II-II′ cross-sectional structure of FIG. 8.

In an embodiment, referring to FIGS. 15, 16 and 17, among the dummy active patterns 9b arranged in the second horizontal direction Y described above, some of the dummy active patterns may be removed in such a way that a pair of dummy active patterns remain, while a pair of dummy active patterns are removed.

The back gate dielectric layers 15 and the back gate electrodes 18 described above may be replaced with back gate dielectric layers 215 and back gate electrodes 218.

When viewed with reference to the first memory cell array region MCA1, the first interface region IF1 and the second memory cell array region MCA2, among the dummy active patterns 9b disposed between the first and second word lines WL_1 and WL_2, a pair of dummy active patterns 9b adjacent to the first memory cell array region MCA1 may remain, among the dummy active patterns 9b disposed between the first and second word lines WL_1 and WL_2, a pair of dummy active patterns (9b in FIG. 6A) adjacent to the second memory cell array region MCA2 may be removed, among the dummy active patterns 9b disposed between the third and fourth word lines WL_3 and WL_4, a pair of dummy active patterns (9b in FIG. 6A) adjacent to the first memory cell array region MCA1 are removed, and among the dummy active patterns 9b disposed between the third and fourth word lines WL_3 and WL_41, a pair of dummy active patterns 9b adjacent to the second memory cell array region MCA2 may remain.

The back gate electrodes 218 passing through the remaining dummy active patterns 9b may have the same shape as the back gate electrodes (18 in FIG. 6A) described above.

The back gate electrodes 218 passing through a portion (in which the dummy active patterns (9b in FIG. 6A) are removed) may have the same shape as the back gate electrodes 118 described in FIGS. 12A, 12B and 13.

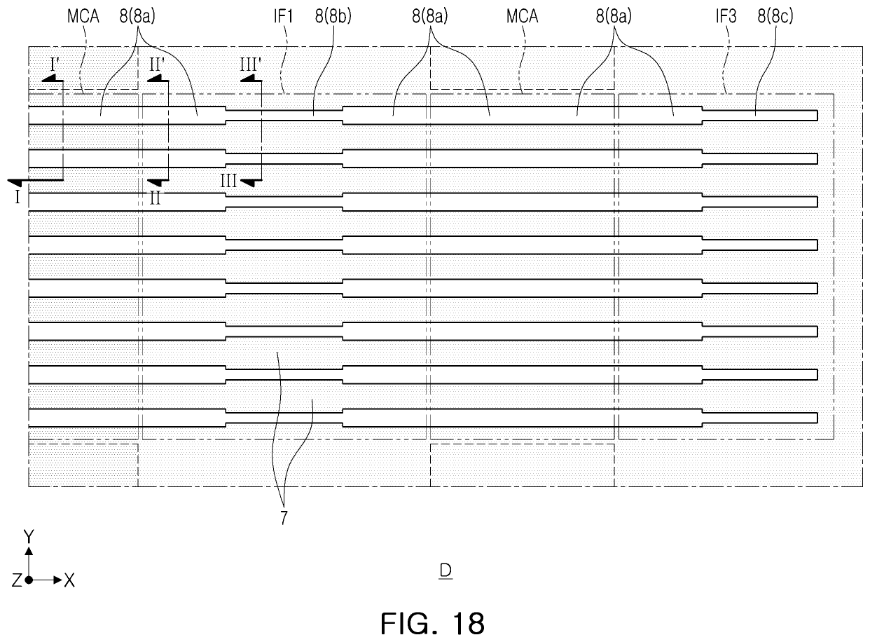

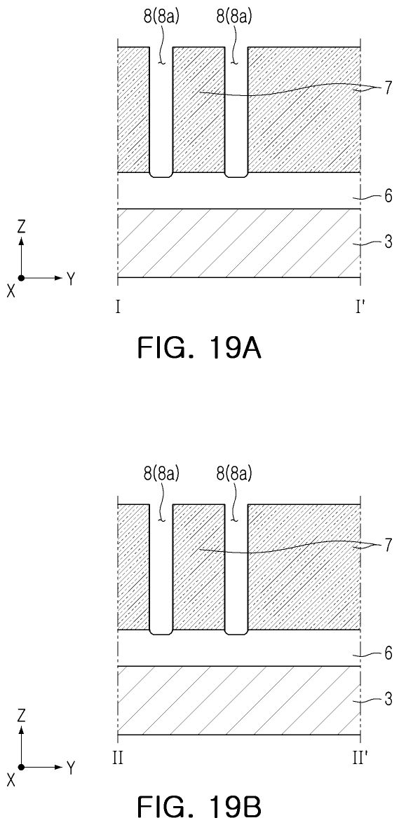

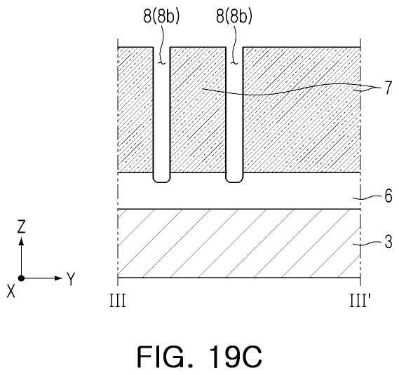

Next, with reference to FIGS. 18, 19A, 19B, 19C, 20, 21A, 21B, 21C, 22A, 22B, 22C, 23A, 23B, 23C, 24A, 24B and 24C along with FIGS. 5A, 5B, 6A, 6B and 6C, an example of a method for forming a semiconductor device according to an embodiment of the present inventive concept will be described. In FIGS. 18, 19A, 19B, 19C, 20, 21A, 21B, 21C, 22A, 22B, 22C, 23A, 23B, 23C, 24A, 24B and 24C, FIGS. 18 and 20 are plan views illustrating the area indicated by ‘D’ in FIG. 5B, FIGS. 19A, 21A, 22A, 23A and 24A are cross-sectional views illustrating the area taken along the line I-I′ in FIGS. 6A and 6C, and FIGS. 19B, 21B, 22B, 23B and 24B are cross-sectional views illustrating the area taken along line the II-II′ in FIGS. 6A and 6C, and FIGS. 19C, 21C, 22C, 23C and 24C are cross-sectional views of the areas taken along the lines III-III′ in FIGS. 6A and 6C. Hereinafter, the description will be focused on a method of forming the elements described above. Since the arrangement or arrangement shape of the elements described above may be understood from the content described above, the description thereof may be omitted.

Referring to FIGS. 18, 19A, 19B and 19C along with FIGS. 5A, 5B, 6A, 6B and 6C, a sacrificial insulating layer 6 may be formed on a base substrate 3. A semiconductor layer 7 may be formed on the sacrificial insulating layer 6. The semiconductor layer 7 may be formed in the memory cell array regions (MCA in FIGS. 2, 3, 5A, 5B, 6A, 6B and 6C) and the interface regions (IF1, IF2 and IF3 in FIGS. 2, 3, 5A, 5B, 6A, 6B and 6C) described above.

The semiconductor layer 7 may be patterned to form openings 8 crossing the memory cell array regions MCA and the first interface regions IF1 and extending into the third interface regions IF3. The openings 8 may penetrate the semiconductor layer 7 and expose the sacrificial insulating layer 6.

Each of the openings 8 may extend in a first horizontal direction X. The openings 8 may be spaced apart from each other in a second horizontal direction Y.

Each of the openings 8 may include first portions 8a having a first width and second and third portions 8b and 8c having a second width less than the first width in the second horizontal direction Y.

In each of the openings 8, the first portions 8a may be formed in the memory cell array regions MCA, the second portions 8b may be formed in a middle region of each of the first interface regions IF1, and the third portions 8c may be formed in regions of the third interface regions IF3 corresponding to the middle region of the first interface region IF1. In each of the openings 8, the first portions 8a may extend across the memory cell array regions MCA to the second and third portions 8b and 8c.

In an embodiment, the middle region of each of the first interface regions IF1 may be the middle region (IF1c in FIG. 6B) of the first interface region IF1 described above.

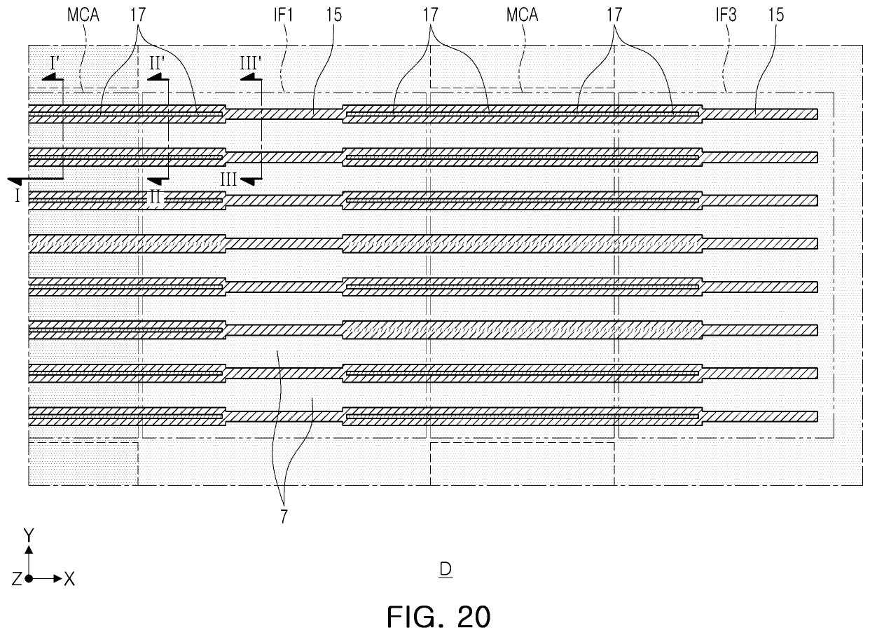

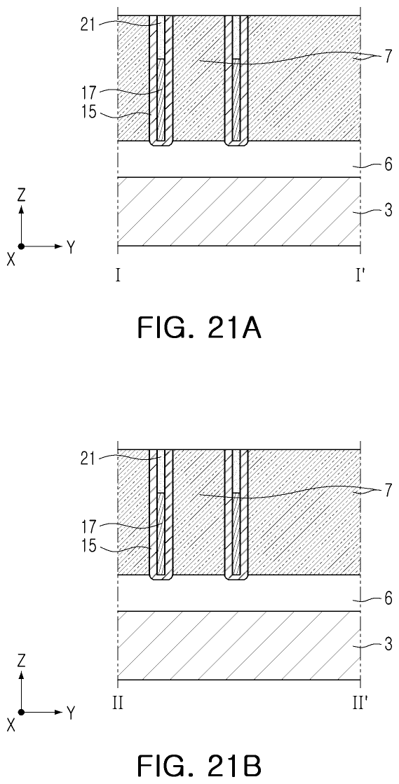

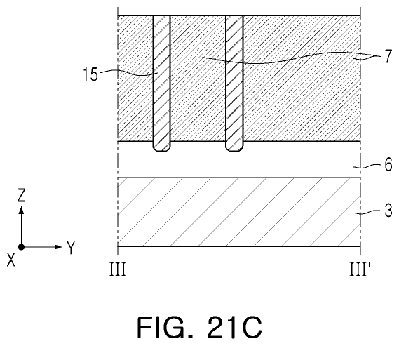

Referring to FIGS. 20, 21A, 21B and 21C along with FIGS. 5A, 5B, 6A, 6B and 6C, back gate structures 15, 17 and 21 may be formed in the openings 8. Forming each of the back gate structures 15, 17 and 21 may include forming a back gate dielectric layer filling the second and third portions 8b and 8c of the openings 8 and conformally covering the first portions 8a of the openings 8, forming a conductive layer on the back gate dielectric layer 15, partially etching the conductive layer to form preliminary back gate electrodes 17 in the first portions 8a, and forming first back gate capping patterns 21 on the preliminary back gate electrodes 17. The preliminary back gate electrodes 17 may not be formed in the second and third portions 8b and 8c of the openings 8.

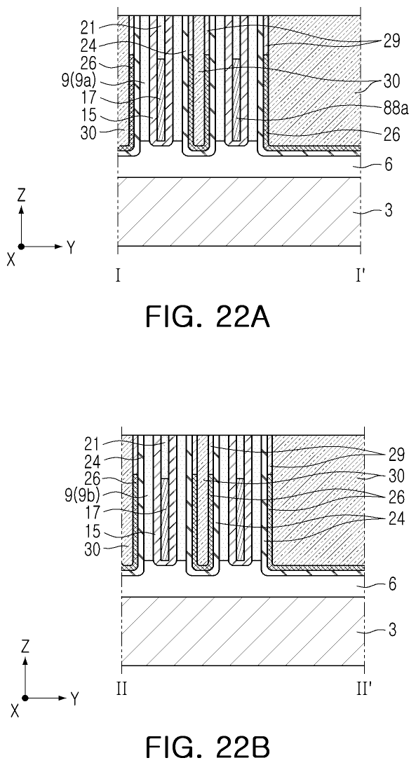

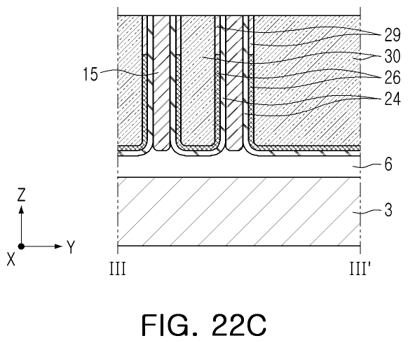

Referring to FIGS. 22A, 22B and 22C along with FIGS. 5A, 5B, 6A, 6B and 6C, the semiconductor layer 7 may be patterned to form active patterns 9. The active patterns 9 may include cell active patterns 9a disposed in the memory cell array regions MCA and the dummy active patterns 9b disposed in the first and third interface regions IF1 and IF3 as described above.

Gate structures 24, 26, 29 and 30 may be formed on side surfaces of the combination of the active patterns 9 and the back gate structures 15, 17 and 21.

Forming the gate structures 24, 26, 29 and 30 may include sequentially forming a cell gate dielectric layer 24 conformally covering the active patterns 9 and the back gate structures 15, 17 and 21 and a preliminary gate layer conformally covering the cell gate dielectric layer 24, forming an insulating layer on the preliminary gate layer, planarizing the insulating layer to form an insulating pattern 30, partially etching the preliminary gate layer exposed by the insulating pattern 30 to form a preliminary gate electrode 26, and forming a first gate capping pattern 29 on the preliminary gate electrode 26.

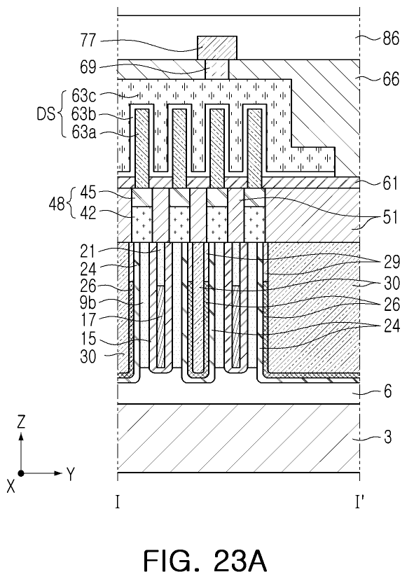

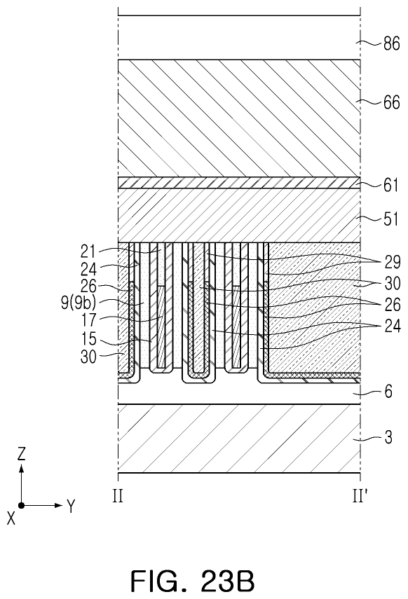

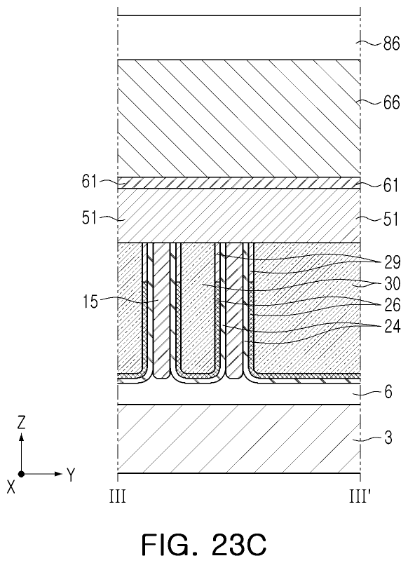

Referring to FIGS. 23A, 23B and 23C along with FIGS. 5A, 5B, 6A, 6B and 6C, contact structures 48 and insulating structures 51 may be formed. The contact structures 48 may be connected to the cell active patterns 9a. Each of the contact structures 48 may include a first material layer 42 and a second material layer 45 on the first material layer 42. The first material layer 42 may include a material such as doped silicon. The second material layer 45 may include at least one of a metal, a metal nitride or a metal-semiconductor compound. The insulating structure 51 may surround side surfaces of the contact structures 48.

An insulating etch-stop layer 61 may be formed on the contact structures 48 and the insulating structure 51. A data storage structure DS may be formed. The data storage structure DS may include first electrodes 63a penetrating the insulating etch-stop layer 61, connected to the contact structures 48 and extending upward, a dielectric layer 63b covering the first electrodes 63a and the etch-stop layer 61, and a second electrode 63c covering the dielectric layer 63b.

A first upper insulating layer 66 may be formed on the data storage structure DS and the insulating etch-stop layer 61. An upper contact plug 69 penetrating the first upper insulating layer 66 may be formed. An upper interconnection 77 may be formed on the first upper insulating layer 66 and the upper contact plug 69. A second upper insulating layer 86 may be formed on the first upper insulating layer 66 and the upper interconnection 77.

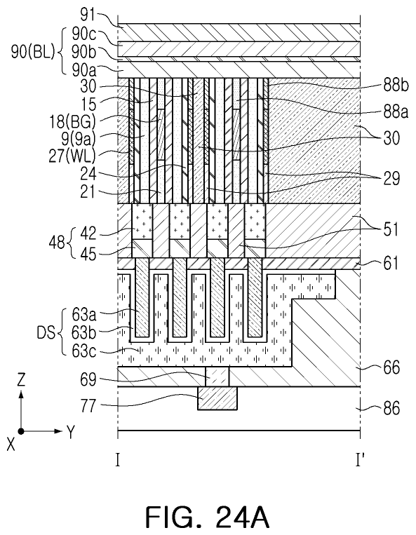

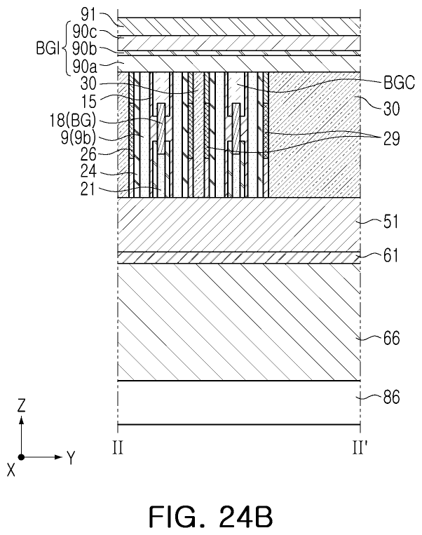

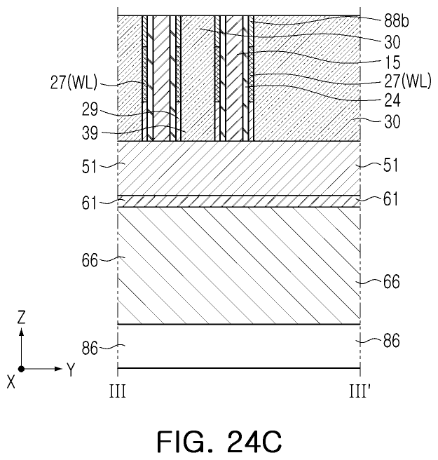

Referring to FIGS. 24A, 24B and 24C along with FIGS. 5A, 5B, 6A, 6B and 6C, after positioning the base substrate 3 to face upward, the base substrate 3 and the sacrificial insulating layer 6 may be removed. The active patterns 9 may be exposed as the sacrificial insulating layer 6 is removed. Subsequently, upper surfaces of the preliminary back gate electrodes 17 and the preliminary gate electrodes 26 may be exposed.

The preliminary back gate electrodes 17 and the preliminary gate electrodes 26 may be partially etched to form back gate electrodes 18 and word lines 27. Insulating capping patterns 88a and 88b may be formed on the back gate electrodes 18 and the word lines 27. The insulating capping patterns 88a and 88b may include insulating gate capping patterns 88b on the word lines 27 and insulating second back gate capping patterns 88a on the back gate electrodes 18.

Back gate contact plugs BGC penetrating the second back gate capping patterns 88a and connected to the back gate electrodes 18 may be formed.

Bit lines 90 and back gate interconnection structures BGI may be formed. Forming the bit lines 90 and the back gate interconnection structures BGI may include sequentially stacking a first material layer 90a, a second material layer 90b and a third material layer 90c, forming insulating capping patterns 91 on the third material layer 90c, performing an etching process using the capping patterns 91 as an etching mask, and patterning the first to third material layers 90a, 90b and 90c.

Again, referring to FIGS. 5A, 5B, 6A, 6B, 6C, 7A, 7B, 8 and 9, an insulating liner 92 conformally covering structures 90, BGI and 91 including the bit lines 90, the back gate interconnect structures BGI and the capping patterns 91 may be formed. A bit line shield pattern 93 may be formed on the insulating liner 92. The bit line shield pattern 93 may be formed between the bit lines 90 and on the capping patterns 91 on the bit lines 90. Subsequently, a first lower insulating layer 97 covering the bit line shield pattern 93 and the insulating liner 92 may be formed. In the second interface region IF2, rear contact plugs 95a and 95b penetrating the first lower insulating layer 94, the insulating liner 92 and the capping pattern 91 may be formed. The rear contact plugs 95a and 95b may include first rear contact plugs 95a connected to the bit lines 90 and second rear contact plugs 95b connected to the back gate interconnection structures BGI.

In the first and third interface regions IF1 and IF3, word line contact plugs WLC penetrating the first lower insulating layer 94, the insulating liner 92 and the gate capping patterns 88b and connected to the word lines 27 may be formed.

Rear interconnections 96a, 96b and WLI may be formed on the first lower insulating layer 94. The rear interconnections 96a, 96b and WLI may include first rear interconnections 96a connected to the first rear contact plugs 95a, second rear interconnections 96b connected to the second rear contact plugs 95b, and third rear interconnections WLI connected to the word line contact plugs WLC.

A second lower insulating layer 98 covering the rear interconnections 96a, 96b and WLI may be formed on the first lower insulating layer 94.

According to embodiments, in each bank area, each word line may cross a plurality of memory cell array regions arranged in a first horizontal direction and interface regions between the plurality of memory cell array regions. Therefore, since a space occupied by the interface regions in each bank area may be minimized, an integration density of the semiconductor device may be increased.

According to embodiments, since each word line WL crossing each memory cell array region is electrically connected to two word line contact plugs arranged on both sides, a transmission speed of a signal applied to the entire word line may be increased. Therefore, a performance of the semiconductor device may be improved.

According to embodiments, a back gate electrode facing a channel region of a cell transistor may be provided. The back gate electrode may suppress or prevent a performance of the cell transistor from being degraded due to a floating body effect.

The various and beneficial advantages and effects of the present inventive concept are not limited to the above-described content, and may be more easily understood through description of specific embodiments of the present inventive concept.

While example embodiments have been shown and described above, it will be apparent to those skilled in the art that modifications and variations could be made without departing from the scope of the present inventive concept as defined by the appended claims.

What is claimed is:

1. A semiconductor device, comprising:
a first memory cell array region and a second memory cell array region spaced apart from each other in a first horizontal direction;
a first interface region between the first and second memory cell array regions;
a first word line and a second word line crossing the first memory cell array region, the first interface region, and the second memory cell array region, and spaced apart from each other in a second horizontal direction perpendicular to the first horizontal direction;
a first back gate electrode between the first and second word lines in the first memory cell array region, and extending into the first interface region; and
a first back gate dielectric layer between the first and second word lines, and crossing the first memory cell array region, the first interface region, and the second memory cell array region,
wherein the first back gate dielectric layer comprises a first portion between the first word line and the first back gate electrode in the first memory cell array region, and a second portion between the second word line and the first back gate electrode in the first memory cell array region.

2. The semiconductor device of claim 1, wherein the first back gate electrode has a first end portion in the first horizontal direction in the first interface region, and
the first back gate dielectric layer covers the first end portion of the first back gate electrode in the first interface region.

3. The semiconductor device of claim 2, further comprising a second back gate electrode between the first and second word lines in the second memory cell array region and extending into the first interface region,
wherein the first back gate dielectric layer further comprises a third portion between the first word line and the second back gate electrode in the second memory cell array region, and a fourth portion disposed between the second word line and the second back gate electrode in the second memory cell array region,
the second back gate electrode has a second end portion facing the first end portion of the first back gate electrode in the first interface region, and
the first back gate dielectric layer covers the second end portion of the second back gate electrode in the first interface region.

4. The semiconductor device of claim 1, further comprising:
first cell active patterns between the first word line and the first back gate dielectric layer in the first memory cell array region;
second cell active patterns between the second word line and the first back gate dielectric layer in the first memory cell array region;
third cell active patterns between the first word line and the first back gate dielectric layer in the second memory cell array region; and
fourth cell active patterns between the second word line and the first back gate dielectric layer in the second memory cell array region.

5. The semiconductor device of claim 4, further comprising:
a first cell gate dielectric layer in contact with the first word line; and
a second cell gate dielectric layer in contact with the second word line,
wherein the first cell active patterns are between the first cell gate dielectric layer and the first back gate dielectric layer in the first memory cell array region, and
the second cell active patterns are between the second cell gate dielectric layer and the first back gate dielectric layer in the first memory cell array region.

6. The semiconductor device of claim 5, wherein the first cell gate dielectric layer extends from portions between the first cell active patterns and the first word line to portions between the first cell active patterns adjacent to each other in the first horizontal direction, and
the second cell gate dielectric layer extends from portions between the second cell active patterns and the second word line to portions between the second cell active patterns adjacent to each other in the first horizontal direction.

7. The semiconductor device of claim 4, further comprising:
a first dummy active pattern between the first word line and the first back gate dielectric layer in the first interface region; and
a second dummy active pattern between the second word line and the first back gate dielectric layer in the first interface region,
wherein the first and second dummy active patterns face each other in the second horizontal direction, and
a length of each of the first and second dummy active patterns is greater than a length of each of the first and second cell active patterns, in the first horizontal direction.

8. The semiconductor device of claim 7, further comprising:
a back gate contact plug connected to a portion of the first back gate electrode located between the first dummy active pattern and the second dummy active pattern.

9. The semiconductor device of claim 8, further comprising:
a first word line contact plug connected to the first word line in the first interface region; and
a second word line contact plug connected to the second word line in the first interface region.

10. The semiconductor device of claim 1, further comprising:
a third memory cell array region spaced apart from the first memory cell array region in the second horizontal direction; and
a second interface region between the third memory cell array region and the first memory cell array region,
wherein the third memory cell array region includes fifth active patterns, and
a distance between the first memory cell array region and the second memory cell array region is greater than a distance between the first memory cell array region and the third memory cell array region.

11. The semiconductor device of claim 10, further comprising:
first bit lines each extending in the second horizontal direction, crossing the first memory cell array region, and extending into the second interface region; and
second bit lines each extending in the second horizontal direction, crossing the second memory cell array region, extending into the second interface region, spaced apart from the first bit lines, and having end portions facing end portions of the first bit lines.

12. A semiconductor device, comprising:
a first memory cell array region and a second memory cell array region spaced apart from each other in a first horizontal direction;
a first interface region between the first and second memory cell array regions; and
word lines crossing the first memory cell array region, the first interface region, and the second memory cell array region, and spaced apart from each other in a second horizontal direction, perpendicular to the first horizontal direction,
wherein the word lines include a first word line and a second word line adjacent to each other, and
a minimum distance between the first and second word lines in the first memory cell array region is greater than a minimum distance between the first and second word lines in the first interface region.

13. The semiconductor device of claim 12, wherein the first and second word lines comprise:
first portions facing each other in the first memory cell array region;
second portions facing each other in the first memory cell array region;
third portions facing each other in the first interface region;
fourth portions facing each other in the first interface region; and
fifth portions facing each other in the first interface region,
wherein a spacing between the first portions is greater than a spacing between the second portions, and
a spacing between the third portions, a spacing between the fourth portions, and a spacing between the fifth portions are different from each other.

14. The semiconductor device of claim 13, wherein the spacing between the third portions is greater than the spacing between the fourth portions, and
the spacing between the fourth portions is greater than the spacing between the fifth portions.

15. The semiconductor device of claim 14, wherein the spacing between the fifth portions is less than the spacing between the second portions.

16. The semiconductor device of claim 13, further comprising:
a first back gate electrode between the first and second word lines,
wherein the first back gate electrode comprises:
a first back gate portion passing between the first portions and between the second portions in the first memory cell array region;
a second back gate portion between the third portions in the first interface region; and
a third back gate portion between the fourth portions in the first interface region, and
the first back gate electrode is not between the fifth portions in the first interface region.

17. The semiconductor device of claim 16, wherein the first back gate portion, the second back gate portion, and the third back gate portion have the same width.

18. The semiconductor device of claim 16, wherein a width of the second back gate portion is greater than a width of each of the first and third back gate portions.

19. A semiconductor device, comprising:
a first structure comprising a first bank area comprising memory cells; and
a second structure comprising a second bank area comprising peripheral circuitry,
wherein the second structure vertically overlaps the first structure,
wherein the first bank area comprises:
a first memory cell array region and a second memory cell array region spaced apart from each other in a first horizontal direction;
a first interface region between the first and second memory cell array regions; and
a first word line and a second word line crossing the first memory cell array region, the first interface region and the second memory cell array region, and spaced apart from each other in a second horizontal direction, perpendicular to the first horizontal direction, and
wherein a minimum distance between the first and second word lines in the first memory cell array region is greater than a separation distance between the first and second word lines in the first interface region.

20. The semiconductor device of claim 19, wherein the first and second structures further comprise a routing interconnection structure electrically connecting the first bank area and the second bank area,
wherein the first bank area further comprises:
a first back gate electrode between the first and second word lines in the first memory cell array region and extending into the first interface region; and
a first back gate dielectric layer between the first and second word lines and crossing the first memory cell array region, the first interface region, and the second memory cell array region, and
wherein the first back gate dielectric layer comprises a first portion between the first word line and the first back gate electrode in the first memory cell array region, and a second portion between the second word line and the first back gate electrode.
